(19) United States
(12) Patent Application Publication
(10) Pub. No.: US 2025/0167107 A1
(43) Pub. Date: May 22, 2025

(54) SEMICONDUCTOR DEVICE INCLUDING THROUGH VIA

(71) Applicant: Samsung Electronics Co., Ltd., Suwon-si (KR)

(72) Inventors: Hyungeun Choi, Suwon-si (KR); Taejin Park, Suwon-si (KR); Suklae Kim, Suwon-si (KR); Cheonbae Kim, Suwon-si (KR); Sungsoo Yim, Suwon-si (KR); Yoona Jang, Suwon-si (KR); Hyunyong Jeong, Suwon-si (KR)

(21) Appl. No.: 18/775,049

(22) Filed: Jul. 17, 2024

(30) Foreign Application Priority Data
Nov. 16, 2023 (KR) 10-2023-0159444
Mar. 20, 2024 (KR) 10-2024-0038485

(51) Int. Cl. H01L 23/522; G11C 5/06; H01L 23/528; H10B 12/00

(52) U.S. Cl. CPC H01L 23/5226; G11C 5/063; H01L 23/5283; H10B 12/312; H10B 12/482; H10B 12/485; H10B 12/488; H10B 12/50

(57) ABSTRACT

A semiconductor device is provided. The semiconductor device includes a first structure having a memory block region and an extension region; and a second structure having a peripheral circuit region. The first structure includes memory cells and a word line. The second structure includes a semiconductor body; a through-insulating pattern in the semiconductor body; and a peripheral transistor. The first and second structures include a word line signal path electrically connecting the word line to the peripheral transistor. The word line signal path includes a word line contact that is in contact with the word line in the extension region; a word line routing lower structure electrically connected to the word line contact and extending from the extension region into the memory block region; and a word line routing connection structure electrically connecting the word line routing lower structure to the word line routing peripheral structure.

### CROSS-REFERENCE TO RELATED APPLICATION(S)

This application claims benefit of priority to Korean Patent Application No. 10-2024-0038485 filed on Mar. 20, 2024 and Korean Patent Application No. 10-2023-0159444 filed on Nov. 16, 2023 in the Korean Intellectual Property Office, the disclosures of which are incorporated herein by reference in their entirety.

### BACKGROUND OF THE INVENTION

Example embodiments of the present disclosure relate to a semiconductor device including a signal path including a through-via and a method of manufacturing the same.

Research has been conducted to reduce sizes of elements included in a semiconductor device and to improve performance. For example, in a dynamic random-access memory (DRAM), research has been conducted to reliably and stably form elements having reduced sizes, but as sizes of the elements are reduced, performance of the semiconductor device may deteriorate.

### SUMMARY OF THE INVENTION

An example embodiment of the present disclosure is to provide a semiconductor device which may increase integration density and may improve performance.

According to an example embodiment, a semiconductor device includes a first structure having a memory block region and an extension region adjacent to the memory block region in a first direction; and a second structure vertically overlapping the first structure and having a peripheral circuit region vertically overlapping the memory block region, wherein the first structure includes memory cells in the memory block region and each including a vertical channel transistor and a data storage structure; and a word line electrically connected to the memory cells, intersecting the memory block region and extending into the extension region, wherein the second structure includes a semiconductor body; a backside insulating layer below the semiconductor body; an isolation region defining peripheral active regions on the semiconductor body; a through-insulating pattern in the semiconductor body; and a peripheral transistor including a first peripheral source/drain, a second peripheral source/drain, a peripheral channel region between the first and second peripheral source/drains, and a peripheral gate on the peripheral channel region, wherein the first and second peripheral source/drains and the peripheral channel region are in a first peripheral active region among the peripheral active regions, wherein the first and second structures include a word line signal path electrically connecting the word line to the peripheral transistor, wherein the word line signal path includes a word line routing peripheral structure electrically connected to the peripheral transistor on the semiconductor body; a word line contact that is in contact with the word line in the extension region; a word line routing lower structure electrically connected to the word line contact and extending from the extension region into the memory block region; and a word line routing connection structure electrically connecting the word line routing lower structure to the word line routing peripheral structure, wherein the word line routing connection structure includes a word line routing through-via vertically overlapping the memory block region and penetrating the semiconductor body.

According to an example embodiment, a semiconductor device includes a first structure having a memory block region and an extension region adjacent to the memory block region in a first direction; and a second structure vertically overlapping the first structure and having a peripheral circuit region vertically overlapping the memory block region, wherein the first structure includes memory cells in the memory block region and each including a vertical channel transistor and a data storage structure; a word line electrically connected to the memory cells, crossing the memory block region and extending into the extension region; and a bit line electrically connected to the memory cells and crossing the memory block region, wherein the second structure includes a semiconductor body, a peripheral transistor, a second peripheral transistor, and through-insulating patterns in the semiconductor body, wherein the first and second structures include a first word line signal path electrically connecting the word line to the peripheral transistor and a bit line signal path electrically connecting the bit line to the second peripheral transistor, wherein the first word line signal path includes a word line routing through-via penetrating the through-insulating pattern among the through-insulating patterns and vertically overlapping the memory block region; a word line contact that is in contact with the word line in the extension region; and a word line routing lower structure electrically connecting the word line contact to the word line routing through-via, wherein the bit line signal path includes a bit line routing through-via penetrating a second through-insulating pattern among the through-insulating patterns and vertically overlapping the memory block region; a bit line contact that is in contact with the bit line; and a bit line routing lower structure electrically connecting the bit line contact to the bit line routing through-via, wherein lower surfaces of the word line routing through-via and the bit line routing through-via are at a level lower than a level of lower surfaces of the through-insulating patterns, and wherein upper surfaces of the word line routing through-via and the bit line routing through-via are at a level higher than a level of upper surfaces of the through-insulating patterns.

According to an example embodiment, a semiconductor device includes a first structure having a first memory block region and a second memory block region adjacent to each other in a first direction, and an extension region between the first memory block region and the second memory block region; and a second structure vertically overlapping the first structure, and including a first peripheral circuit region vertically overlapping the first memory block region, and a second peripheral circuit region vertically overlapping the second memory block region, wherein the first structure includes memory cells in the first and second memory block regions, respectively, and each including a vertical channel transistor and a data storage structure; and a word line crossing the first and second memory block regions and the extension region and electrically connected to the memory cells in the first and second memory block regions, wherein the second structure includes a semiconductor body, peripheral transistors and through-insulating patterns in the semiconductor body, wherein the first and second structures include a first word line signal path electrically connecting the word line to the peripheral transistor among the peripheral transistors, wherein the first word line signal path includes a word line routing through-via penetrating a through-insulating pattern among the through-insulating patterns and vertically overlapping the first memory block region; a word line contact that is in contact with the word line in the extension region; and a word line routing lower structure electrically connecting the word line contact to the word line routing through-via, wherein a lower surface of the word line routing through-via is at a level lower than a level of lower surfaces of the through-insulating patterns, and wherein an upper surface of the word line routing through-via is at a level higher than a level of upper surfaces of the through-insulating patterns.

### BRIEF DESCRIPTION OF DRAWINGS

The above and other aspects, features, and advantages in the example embodiments will be more clearly understood from the following detailed description, taken in combination with the accompanying drawings, in which:

FIGS. 1A, 113, 2A-2C, 3A-3C, 4A-4D, 5, and 6 are diagrams illustrating a semiconductor device according to an example embodiment of the present disclosure;

FIG. 7 is an enlarged cross-sectional diagram illustrating a portion of a semiconductor device according to an example embodiment of the present disclosure;

FIG. 8A is an enlarged cross-sectional diagram illustrating a portion of a semiconductor device according to an example embodiment of the present disclosure;

FIG. 8B is an enlarged cross-sectional diagram illustrating a portion of a semiconductor device according to an example embodiment of the present disclosure;

FIG. 8C is an enlarged cross-sectional diagram illustrating a portion of a semiconductor device according to an example embodiment of the present disclosure;

FIG. 9 is an enlarged cross-sectional diagram illustrating a semiconductor device according to an example embodiment of the present disclosure;

FIGS. 10A, 10B, and 11 are diagrams illustrating a semiconductor device according to an example embodiment of the present disclosure;

FIG. 12 is a cross-sectional diagram illustrating a semiconductor device according to an example embodiment of the present disclosure;

FIG. 13 is a cross-sectional diagram illustrating a semiconductor device according to an example embodiment of the present disclosure;

FIG. 14 is a cross-sectional diagram illustrating a semiconductor device according to an example embodiment of the present disclosure;

FIG. 15 is a cross-sectional diagram illustrating a semiconductor device according to an example embodiment of the present disclosure;

FIGS. 16A and 16B are cross-sectional diagrams illustrating a semiconductor device according to an example embodiment of the present disclosure; and

FIGS. 17A-17D, 18A, 1813, 19A, and 19B are cross-sectional diagrams illustrating a method of manufacturing a semiconductor device according to an example embodiment of the present disclosure.

### DETAILED DESCRIPTION

Hereinafter, example embodiments will be described as follows with reference to the accompanying drawings.

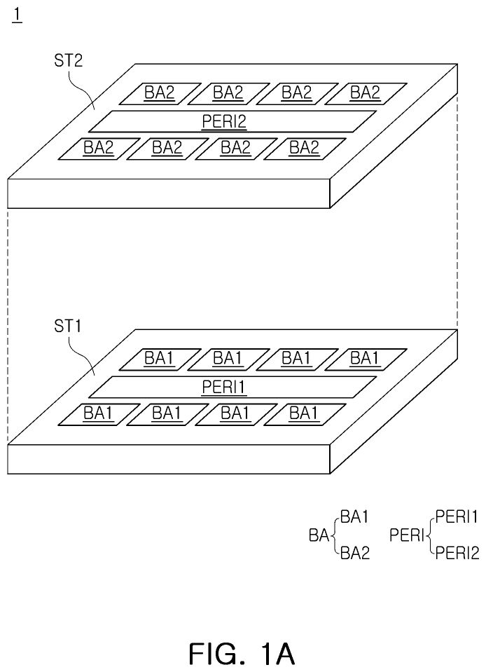

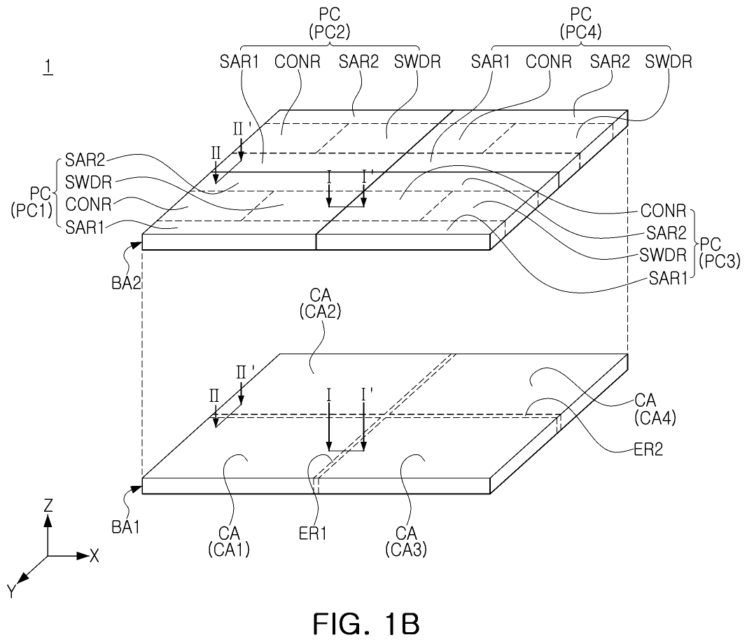

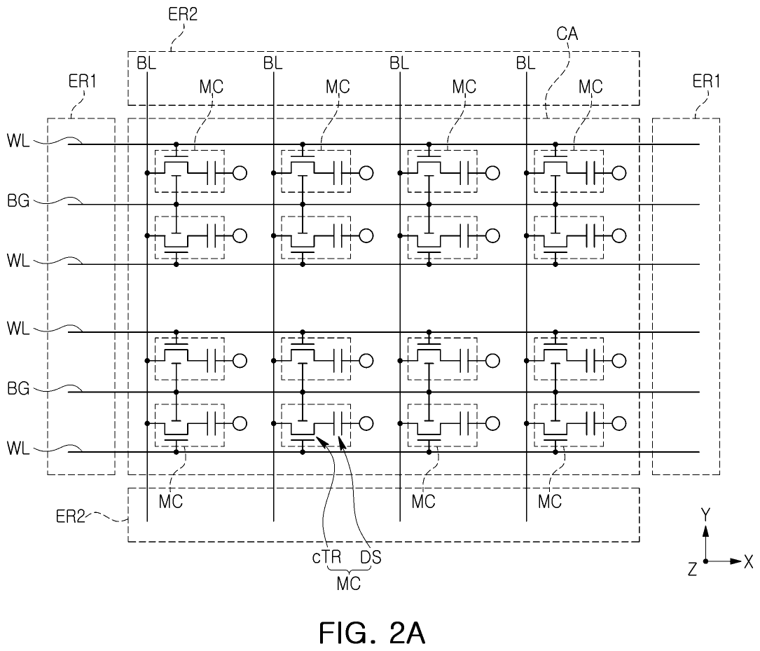

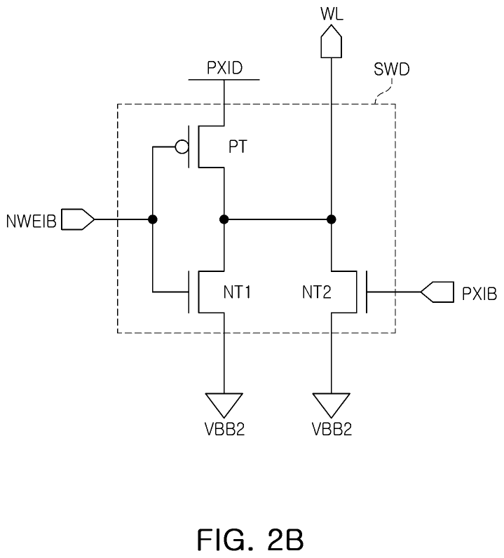

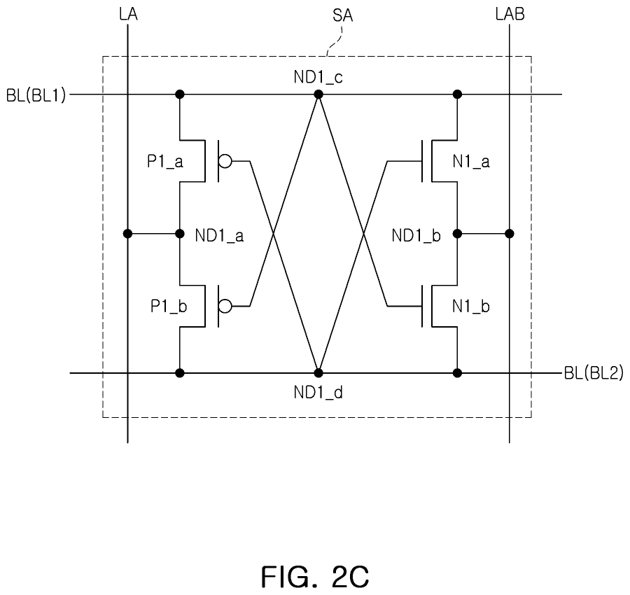

An example of a semiconductor device according to an example embodiment will be described with reference to FIGS. 1A, 1B, 2A, 2B and 2C. FIG. 1A is a perspective diagram illustrating an example of a semiconductor device according to an example embodiment. FIG. 1B is a perspective diagram illustrating a portion of a bank BA in FIG. 1A. FIG. 2A is a circuit diagram illustrating an example of a memory block in a memory block region of a semiconductor device according to an example embodiment. FIG. 2B is a circuit diagram illustrating an example of a sub-word line driver in a peripheral circuit region of a semiconductor device according to an example embodiment. FIG. 2C is a circuit diagram illustrating an example of a sense amplifier in a peripheral circuit region of a semiconductor device according to an example embodiment.

Referring to FIGS. 1A, 1B, 2A, 2B and 2C, a semiconductor device 1 according to an example embodiment may include a first structure ST1 and a second structure ST2 vertically overlapping the first structure ST1. The second structure ST2 may be disposed on the first structure ST1.

In an example embodiment, the first structure ST1 may be configured as a first chip structure including memory cells, and the second structure ST2 may be configured as a second chip structure including a peripheral circuit for operating memory cells MC.

The first structure ST1 and the second structure ST2 may be formed by bonding through a bonding process such as a wafer bonding process. Accordingly, the first structure ST1 may be in contact with and bonded to the second structure ST2.

The semiconductor device 1 may include a plurality of banks BA and an external peripheral region PERI.

The external peripheral region PERI may include a first peripheral region PERI1 in the first structure ST1 and a second peripheral region PERI2 in the second structure ST2. The external peripheral region PERI may be configured as a peripheral circuit region in which peripheral circuits for data or command input/output, or power/ground input are disposed.

Each of the plurality of banks BA may include a first bank region BA1 in the first structure ST1 and a second bank region BA2 in the second structure ST2.

The first bank region BA1 in the first structure ST1 may include memory block regions CA and extension regions ER1 and ER2. The extension regions ER1 and ER2 may also be referred to as connection regions.

The memory block regions CA may be arranged in the first direction X and the second direction Y. The first direction X and the second direction Y may be perpendicular to each other.

The memory block regions CA may include first to fourth memory block regions CA1, CA2, CA3, and CA4 adjacent to each other. For example, the first memory block region CA1 and the second memory block region CA2 may be adjacent to each other in the second direction Y, the third memory block region CA3 and the fourth memory block region CA4 may be adjacent to each other in the second direction Y, the first memory block region CA1 and the third memory block region CA3 may be adjacent to each other in the first direction X, and the second memory block region CA2 and the fourth memory block region CA4 may be adjacent to each other in the first direction X.

The extension regions ER1 and ER2 may include a first extension region ER1 and a second extension region ER2. The first extension region ER1 may be disposed between the first memory block region CA1 and the third memory block region CA3, and may be disposed between the second memory block region CA2 and the fourth memory block region CA4. The second extension region ER2 may be disposed between the first memory block region CA1 and the second memory block region CA2, and between the third memory block region CA3 and the fourth memory block region CA4.

The second bank region BA2 in the second structure ST2 may include peripheral circuit regions PC. The peripheral circuit regions PC may be arranged in the first direction X and the second direction Y. The peripheral circuit regions PC may overlap the memory block regions CA in the vertical direction Z.

The peripheral circuit regions PC may include a first peripheral circuit region PC1 vertically overlapping the first memory block region CA1, a second peripheral circuit region PC2 vertically overlapping the second memory block region CA2, a third peripheral circuit region PC3 vertically overlapping the third memory block region CA3, and a fourth peripheral circuit region PC4 vertically overlapping the fourth memory block region CA4.

Each of the peripheral circuit regions PC may include sense amplifier regions SAR1 and SAR2, a sub-word line driver region SWDR and an internal peripheral region CONR. In each of the peripheral circuit regions PC, the sense amplifier regions SAR1 and SAR2 may include a first sense amplifier region SAR1 and a second sense amplifier region SAR2 spaced apart from each other in the second direction Y. In each of the peripheral circuit regions PC, the sub-word line driver region SWDR and the peripheral region CONR may be disposed between the first sense amplifier region SAR1 and the second sense amplifier region SAR2. In each of the peripheral circuit regions PC, the internal peripheral region CONR may include a control circuit for controlling the sense amplifier SA of the sense amplifier regions SAR1 and SAR2 and the sub-word line driver SWD of the sub-word line driver region SWDR.

Each of the memory block regions CA may include memory cells MC arranged in the first direction X and the second direction Y, word lines WL connected to the memory cells MC and extending in the first direction X, and bit lines BL connected to the memory cells MC and extending in the second direction Y.

The word lines WL may cross the memory block regions CA and may extend in the first extension regions ER1. The bit lines BL may cross the memory block regions CA and may extend into the second extension regions ER2.

Each of the memory cells MC may include a cell transistor cTR and a data storage structure DS which may work as data storage. In a memory such as a DRAM, the data storage structure DS may be configured as a cell capacitor which may store data.

Each of the memory block regions CA may further include back gate lines BG. Each of the back gate lines BG may be disposed between a pair of word lines WL adjacent to each other in the second direction Y among the word lines WL. Each of the back gate lines BG may be disposed between channel regions of the cell transistors cTR. The back gate lines BG may cross the memory block regions CA and may extend into the first extension regions ER1.

Each of the sub-word line driver regions SWDR may include sub-word line drivers SWD. The sub-word line drivers SWD may be electrically connected to the word lines WL.

Each of the sub-word line drivers SWD may include a PMOS transistor PT, a first NMOS transistor NT1, and a second NMOS transistor NT2. The driving signal PXID may be connected to a source terminal of the PMOS transistor PT, the word line WL may be electrically connected to a drain terminal of the PMOS transistor PT, and the word line enable signal NWEIB may be connected to a gate terminal of the PMOS transistor PT. The PMOS transistor PT may be configured as a pull-up transistor. A precharge voltage corresponding to the back bias voltage VBB2 may be connected to a source terminal of the first NMOS transistor NT1, the word line WL may be electrically connected to a drain terminal of the first NMOS transistor NT1, and the word line enable signal NWEIB may be connected to a gate terminal of the first NMOS transistor NT1. The first NMOS transistor NT1 may be configured as a pull-down transistor. A complementary driving signal PXIB may be connected to a gate terminal of the second NMOS transistor NT2, a precharge voltage corresponding to the back bias voltage VBB2 may be connected to a source terminal of the second NMOS transistor NT2, and the word line WL may be electrically connected to a drain terminal of the second NMOS transistor NT2. The second NMOS transistor NT2 may be configured as a keeping transistor for maintaining the word line WL at a ground voltage level when the word line WL is not selected. The second NMOS transistor NT2 may be connected in parallel to the first NMOS transistor NT1. The sub-word line driver SWD may drive the word line WL in response to the word line enable signal NWEIB and the driving signal PXID. The PMOS transistor PT may pull-up the word line WL to a level of the driving signal PXID in response to the word line enable signal NWEIB. The first NMOS transistor NT1 may pull down the word line WL to a level of negative voltage VBB2 in response to the word line enable signal NWEIB. The second NMOS transistor NT2, which may be a keeping transistor, may maintain the word line WL at a level of the negative voltage VBB2 at a time point at which the word line WL becomes inactive. To this end, the second NMOS transistor NT2 may switch between a source providing negative voltage VBB2 and a drain electrically connected to the word line WL in response to the driving signal PXIB, which is complementary to the driving signal PXID. A circuit of the sub-word line drivers SWD described above may be merely an example, and the circuit of the sub-word line drivers SWD may be implemented with various circuit elements.

Each of the sense amplifier regions SAR1 and SAR2 may include sense amplifiers SA. Each of the sense amplifiers SA may include a plurality of transistors P1_a, P1_b, N1_a, and N1_b. The transistors P1_a, P1_b, N1_a, and N1_b may include a transistor P1_a and a transistor P1_b, which are PMOS transistors, and a transistor N1_a and a transistor N1_b, which are NMOS transistors. The transistor P1_a and the transistor P1_b may be referred to as a PMOS transistor pair, and the transistor N1_a and the transistor N1_b may be referred to as an NMOS transistor pair. A source of the transistor P1_a and a source of the transistor P1_b may be connected to the first control line LA through a first node ND1_a. A source of the transistor N1_a and a source of the transistor N1_b may be connected to the second control line LAB through the second node ND1_b. The first node ND1_a and the second node ND1_b may be referred to as a first source node and a second source node, respectively. A drain of the transistor P1_a and a drain of the transistor N1_a may be connected to the first bit line BL1 among the bit lines BL through the first drain node ND1_c. A drain of the transistor P1_b and a drain of the transistor N1_b may be connected to a complementary bit line BL2 among the bit lines BL through the second drain node ND1_d. The sense amplifier SA may sense a voltage change of the first bit line BL1 and amplify the same. When the sense amplifier SA performs a sensing and amplifying operation, an internal power voltage may be applied to the first node ND1_a through the first control line LA, and the second node ND1_b may be connected to a ground terminal through the second control line LAB. The sense amplifier SA may include a PMOS transistor pair and an NMOS transistor pair, and may be implemented as a circuit element in which transistors are cross-coupled, but this is merely an example embodiment and the present disclosure is thus not limited thereto. For example, a circuit of the sense amplifier SA may be implemented with various circuit elements.

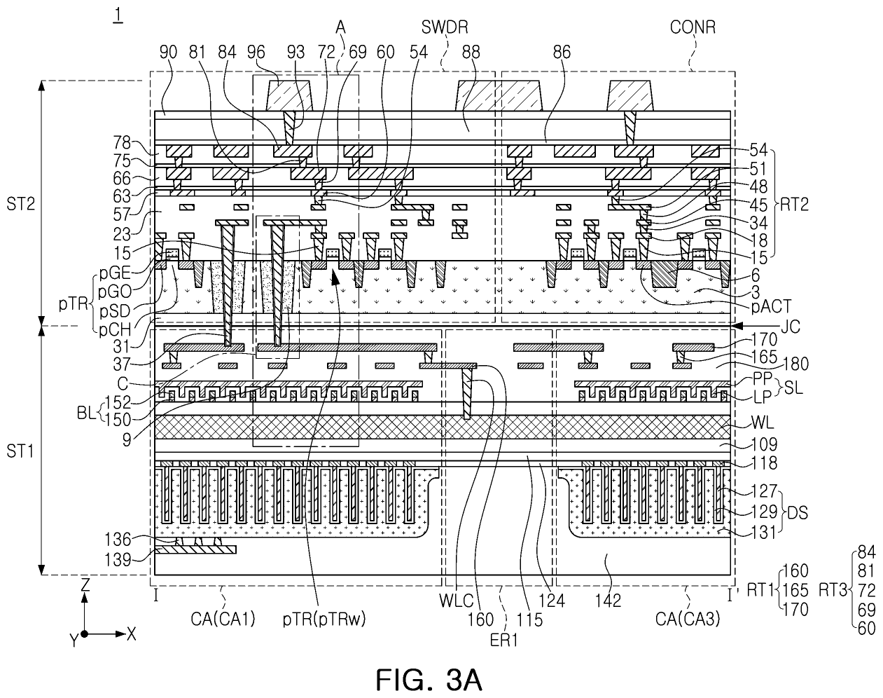

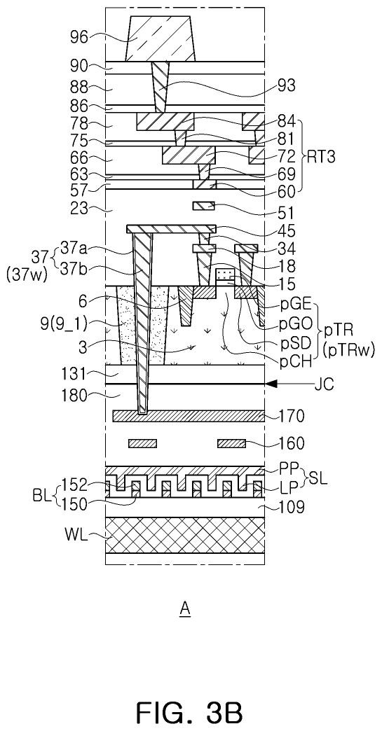

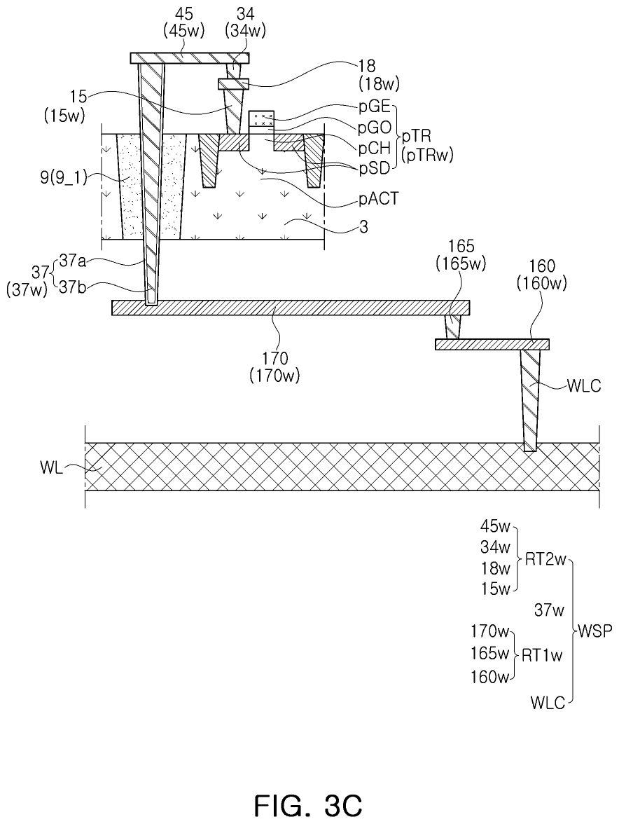

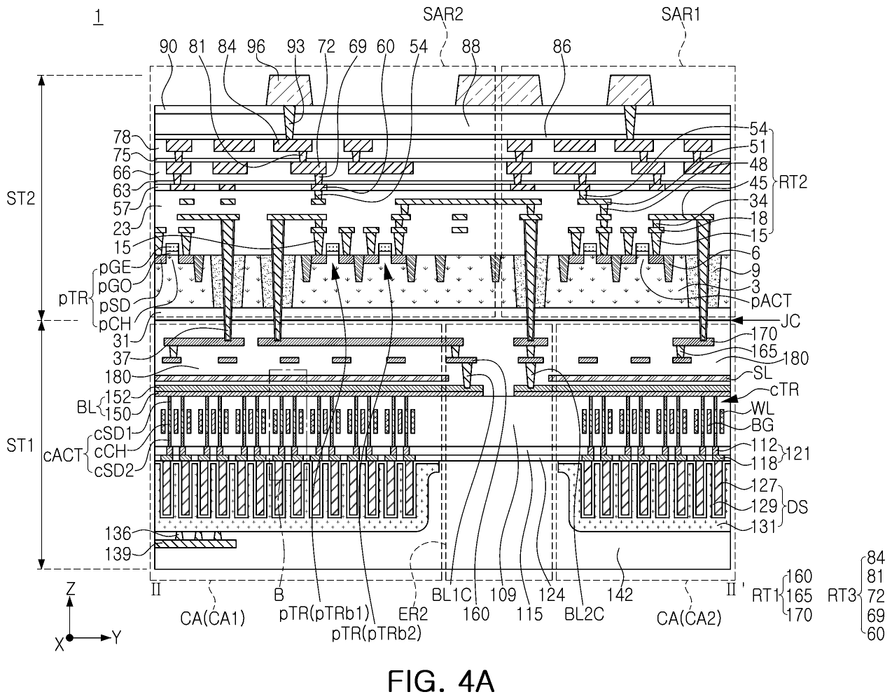

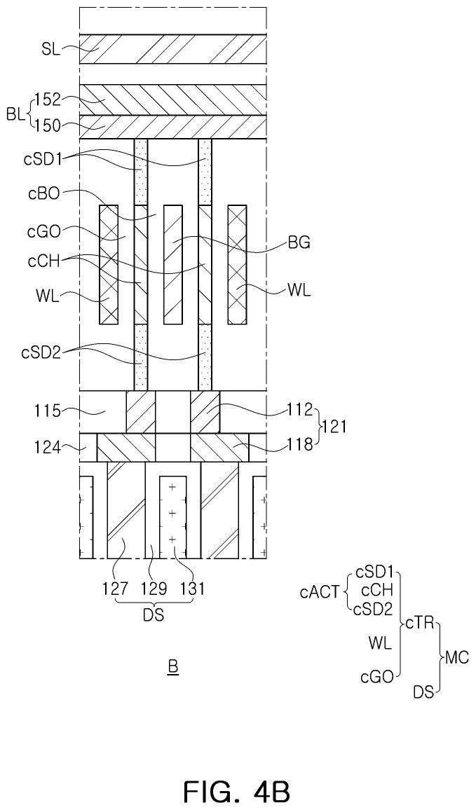

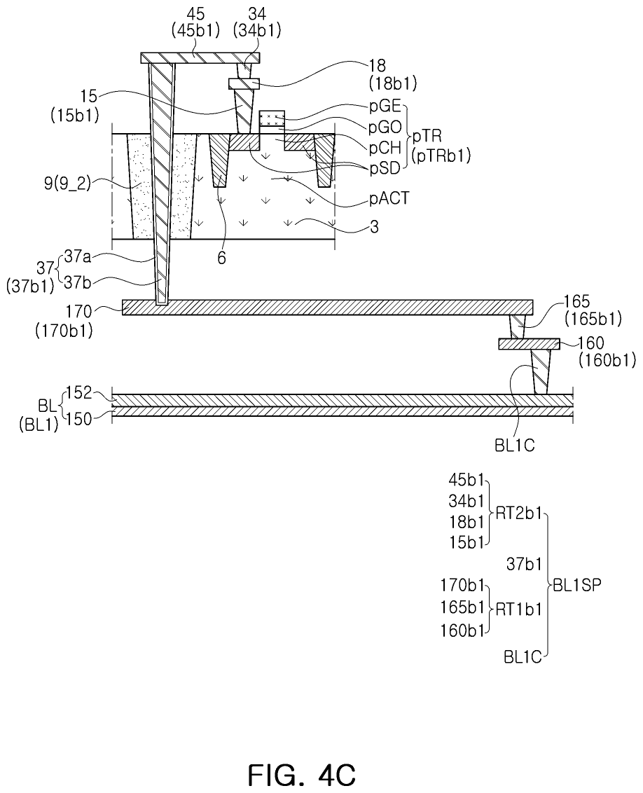

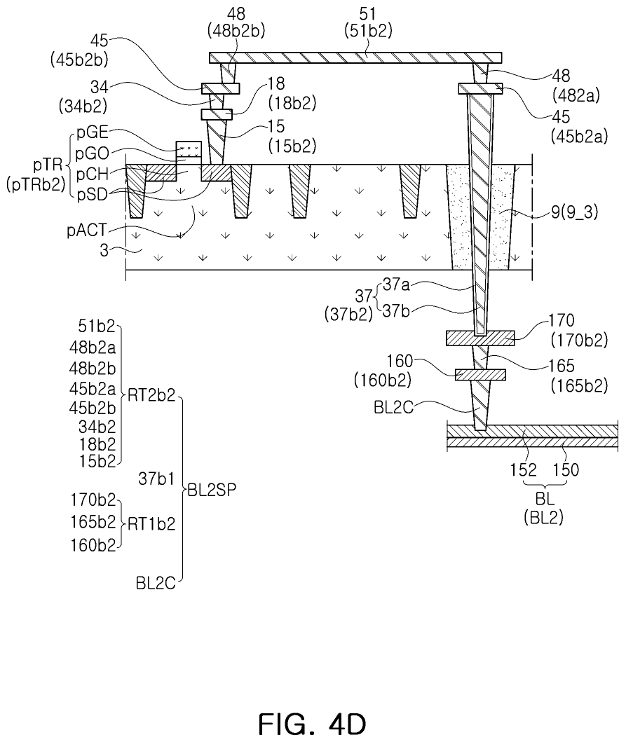

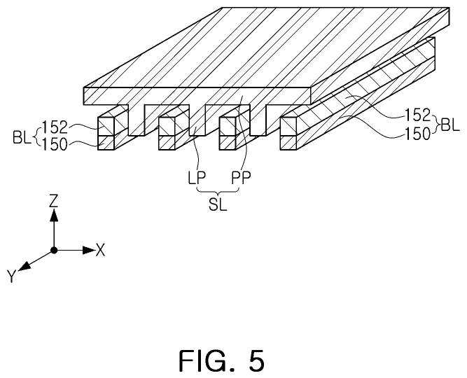

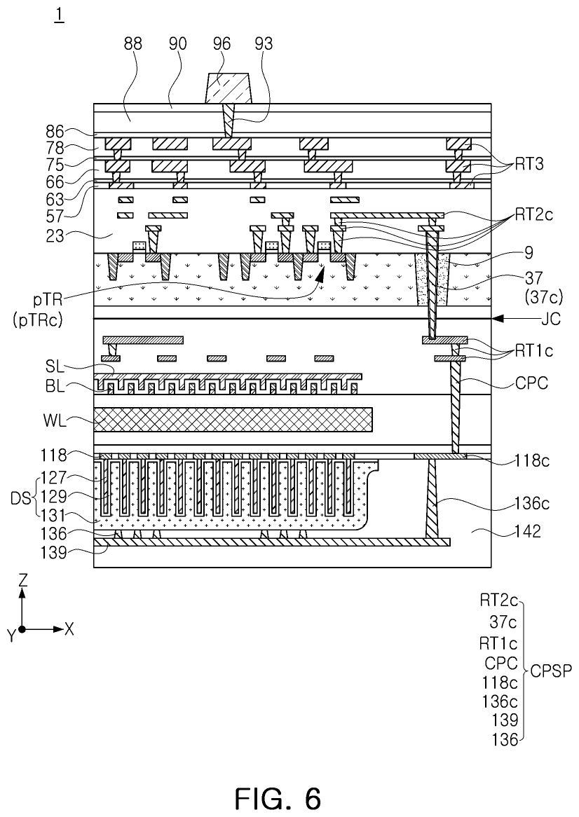

In the description below, an example of the cross-sectional structure of the semiconductor device 1 described above will be described with reference to FIGS. 3A, 3B, 3C, 4A, 4B, 4C, 4D, 5 and 6. FIG. 3A is a cross-sectional diagram illustrating a region taken along line I-I′ in FIG. 1B. FIG. 3B is an enlarged diagram illustrating region “A” in FIG. 3A. FIG. 3C is a cross-sectional diagram illustrating a word line signal path WSP. FIG. 4A is a cross-sectional diagram illustrating a region taken along line II-II′ in FIG. 1B. FIG. 4B is an enlarged diagram illustrating region “B” of FIG. 4A. FIG. 4C is a cross-sectional diagram illustrating a first bit line signal path BL1SP according to an example embodiment. FIG. 4D is a cross-sectional diagram illustrating a second bit line signal path BL2SP according to an example embodiment. FIG. 5 is a perspective diagram illustrating a bit lines BL and a conductive shield structure SL according to an example embodiment. FIG. 6 is a cross-sectional diagram illustrating a signal path CPSP of a second electrode of a data storage structure DS according to an example embodiment.

Referring to FIGS. 3A to 6 along with FIGS. 1A to 2C, in a first stack structure ST1, a word line WL may cross memory block regions CA and a first extension region ER1. For example, the word line WL may cross a first memory block region CA1, a third memory block region CA3, and a first extension region ER1 between the first and third memory block regions CA1 and CA3 without being disconnected.

In the first stack structure ST1, the data storage structures DS may be disposed at a level lower than a level of the word line WL.

Each of the data storage structures DS may include first electrodes 127 extending in the vertical direction Z, a second electrode 131 covering a side surface and a lower surface of each of the first electrodes 127, and a dielectric layer 129 between the first electrodes 127 and the second electrode 131.

The data storage structures DS may be cell capacitors which may store data in a memory such as a DRAM, but an example embodiment thereof is not limited thereto. For example, the data storage structures DS may be configured as a data storage structure of magnetoresistive RAM (MRAM) or a data storage structure of ferroelectric RAM (FeRAM).

The first stack structure ST1 may further include cell active patterns cACT.

Each of the cell active patterns cACT may include a first source/drain region cSD1, a second source/drain region cSD2 disposed at a level different from a level of the first source/drain region cSD1, and a vertical channel region cCH between the first and second source/drain regions cSD1 and cSD2. The first source/drain region cSD1 may be disposed at a level higher than a level of the second source/drain region cSD2. The cell active patterns cACT may also be referred to as a cell semiconductor layer or a vertical channel layer.

Each of the cell transistors cTR may include the first source/drain region cSDc1, the second source/drain region cSD2, the vertical channel region cCH, the word line WL opposing a side surface of the vertical channel region CHc, and a gate dielectric layer cGO between the cell active pattern cACT and the word line WL. The cell transistors cTR may thus be vertical channel transistors. In the word line WL, a portion opposing the vertical channel region cCH may be configured as a gate electrode.

The gate dielectric layer cGO may be in contact with a side surface of the cell active pattern cACT of the vertical channel region cCH, and the gate electrode portion of the word line WL may be in contact with the gate dielectric layer cGO.

The back gate line BG may face a side surface of the vertical channel region CHc. A back gate dielectric layer cBO may be disposed between the back gate line BG and the vertical channel region CHc. The vertical channel region CHc may be disposed between the back gate line BG and the word line WL. A pair of cell active patterns cACT adjacent to each other may be disposed between a pair of word lines WL adjacent to each other, and the back gate line BG may be disposed between a pair of cell active patterns cACT adjacent to each other. The back gate line BG may be configured as a back gate electrode.

The back gate line BG may control charges accumulated in the vertical channel region cCH. The vertical channel region cCH may be configured as a floating body disposed between the first and second source/drain regions cSD1 and cSD2, the back gate line BG may suppress or prevent performance degradation of the cell transistor cTR due to a floating body effect, and performance of the cell transistor cTR may be improved. For example, the back gate line BG may reduce or may prevent changes in a threshold voltage of the cell transistor cTR by accumulating charges, for example, holes, in the floating body of the vertical channel region CHc during operation of the cell transistor cTR.

The word lines WL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or a combination thereof, but an example embodiment thereof is not limited thereto. Each of the word lines WL may include a single layer or multiple layers of the conductive materials described above. The back gate lines BG may include at least one conductive material. For example, each of the back gate lines BG may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or a combination thereof, but an example embodiment thereof is not limited thereto. Each of the back gate lines BG may include a single layer or multiple layers of the materials described above.

The first structure ST1 may further include contact structures 121 electrically connecting the second source/drain regions cSD2 to the first electrodes 127.

Each of the contact structures 121 may include a plug portion 112 in contact with the cell active pattern cACT and a pad portion 118 below the plug portion 112. The data storage structures DS may be disposed below the pad portions 118.

The bit lines BL may be connected to the cell active patterns cACT on the cell active patterns cACT. For example, the bit lines BL may be electrically connected to the first source/drain regions cSD1 of the cell active patterns cACT. Accordingly, the bit lines BL may be electrically connected to the cell transistors cTR.

Each of the bit lines BL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or a combination thereof, but an example embodiment thereof is not limited thereto. Each of the bit lines BL may include a single layer or multiple layers of the above-described conductive materials. For example, each of the bit lines BL may include a first conductive layer 150 and a second conductive layer 152 on the first conductive layer 150. The first conductive layer 150 may include doped silicon, and the second conductive layer 152 may include a conductive material having lower resistivity than that of the doped silicon among the aforementioned conductive materials.

The first structure ST1 may further include a shield conductive structure SL including line portions LP alternately arranged with the bit lines BL and a connection portion PP extending from the line portions LP and covering upper surfaces of the bit lines BL. The connection portion PP may have a plate shape. The shield conductive structure SL may be spaced apart from the bit lines BL. The shield conductive structure SL may screen capacitive coupling between the bit lines BL. For example, the shield conductive structure SL may reduce or block parasitic capacitance between the bit lines BL, thereby reducing a resistive-capacitive delay (RC delay) of the bit lines BL.

The first structure ST1 may further include a routing lower structure RT1. The routing lower structure RT1 may include first horizontal portions 160, vertical vias 165 on the first horizontal portions 160, and second horizontal portions 170 on the vertical vias 165. The first and second horizontal portions 160 and 170 may be configured as redistribution lines for routing, and the vertical vias 165 may be configured as conductive vias.

The first structure ST1 further may include first and second bit line contacts BL1C and BL2C electrically connecting the routing lower structure RT1 to the bit lines BL, and word line contacts WLC electrically connecting the routing lower structure RT1 to the word lines WL.

The first structure ST1 may further include a capacitor vias 136 below the second electrodes 131, a capacitor interconnection 139 disposed below the capacitor vias 136 and extending externally of the data storage structure DS, an intermediate pad 118c disposed at the same vertical level as a level of the pad portions 118, a first contact plug 136c between the intermediate pad 118c and the capacitor interconnection 139, and a second contact plug CPC disposed on the intermediate pad 118c and connected to the lower routing structure RT1.

The first structure ST1 may further include the first insulating structure 142, the second insulating layer 124 on the first insulating structure 142, the third insulating layer 115 on the second insulating layer 124, the fourth insulating structure 109 on the third insulating layer 115 and the fifth insulating structure 180 on the fourth insulating structure 109.

The data storage structures DS may be disposed in the first insulating structure 142. The second insulating layer 124 may be disposed on side surfaces of the pad portions 118. The third insulating layer 115 may be disposed on side surfaces of the plug portions 112. The cell transistors cCT and the back gate line BG may be disposed in the fourth insulating structure 109. The bit lines BL, the conductive shield structure SL, the bit line contacts BLC, the word line contacts WLC, and the routing lower structure RT1 may be disposed in the fifth insulating structure 180.

The second structure ST2 may include a semiconductor body 3 including the peripheral active regions pACT, an isolation region 6 defining the peripheral active regions pACT on the semiconductor body 3, and through-insulating patterns 9 penetrating the semiconductor body 3. The isolation region 6 may define side surfaces of the peripheral active regions pACT. The isolation region 6 may be formed of an insulating material. The through-insulating patterns 9 may have lower surfaces coplanar with a lower surface of the semiconductor body 3, and upper surfaces coplanar with the upper surface of the isolation region 6. The through-insulating patterns 9 may include at least one of low-dielectric, silicon oxide, silicon nitride, SiBN, SiCN, SiON, SiOCN, impurity doped silicon oxide, or impurity doped silicon nitride.

The semiconductor body 3 may include a semiconductor material, such as a group IV semiconductor, a group III-V compound semiconductor, or a group II-VI compound semiconductor. For example, a group IV semiconductor may include silicon, germanium, or silicon-germanium. The semiconductor body 3 may include single crystal silicon. The semiconductor body 3 may have a thickness ranging from about 0.5 micrometers (km) to about 2 km.

The second structure ST2 may further include peripheral transistors PTR, a first peripheral interconnection structure RT2 and a second peripheral interconnection structure RT3 disposed on the semiconductor body 3.

Each of the peripheral transistors PTR may include peripheral source/drain regions pSD disposed in the peripheral active region pACT, peripheral channel region pCH between the peripheral source/drain regions pSD, and a peripheral gate pGO and pGE on the peripheral channel region pCH. The peripheral gate pGO and pGE may include a peripheral gate dielectric layer pGO and a peripheral gate electrode pGE on the peripheral gate dielectric layer pGO. The peripheral transistors PTR may include NMOS transistors and PMOS transistors. When the peripheral transistor PTR is configured as an NMOS transistor, the peripheral source/drain regions pSD may have N-type conductivity, and when the peripheral transistor PTR is configured as a PMOS transistor, the peripheral source/drain regions pSD may have P-type conductivity.

The peripheral transistors PTR may include the transistors PT, NT1, and NT2 of the sub-word line driver (SWD in FIG. 2B) and the transistors P1_a, P1_b, N1_a, and N1_b of the sense amplifier (SA in FIG. 2C).

In example embodiments, the transistors PT, NT1, and NT2 of the sub-word line driver (SWD in FIG. 2B) may be disposed in the sub-word line driver region SWDR, and the transistors P1_a, P1_b, N1_a, and N1_b of the sense amplifier (SA in FIG. 2C) may be disposed in the sense amplifier region SAR.

As an example, in the drawing, the peripheral transistors PTR may be configured as a first peripheral transistor PTRw which may be one of transistors PT, NT1, and NT2 of the sub-word line driver (SWD in FIG. 2B), and the second and third peripheral transistors PTRb1 and pTRb2 may be configured as the transistors P1_a, P1_b, N1_a, and N1_b of the sense amplifier (SA in FIG. 2C).

The first peripheral interconnection structure RT2 may include vertical plugs 15, first horizontal portions 18 disposed at a level higher than a level of the vertical plugs 15, first vertical vias 34 on the first horizontal portions 18, second horizontal portions 45 disposed at a level higher than a level of the first vertical vias 34, second vertical vias 48 on the second horizontal portions 45, third horizontal portions 51 disposed at a level higher than a level of the second vertical vias 48, and third vertical vias 54 on the third horizontal portions 51.

The through-vias 37 may be disposed at a level higher than a level of the first horizontal portions 18. The through-vias 37 may be disposed at a level lower than a level of the second horizontal portions 45. The through-vias 37 and the second horizontal portions 45 may include through-vias 37 and second horizontal portions 45 in contact with each other.

The second peripheral interconnection structure RT3 may include first horizontal portions 60, first vertical vias 69 on the first horizontal portions 60, second horizontal portions 72 on the first vertical vias 69, third vertical vias 81 on the second horizontal portions 72, and fourth horizontal portions 84 on the third vertical vias 81. The horizontal portions 60, 72, and 84 may be configured as peripheral interconnection lines for routing.

The second structure ST2 may further include upper vias 93 on the second horizontal portions 84 and upper interconnections 96 on the upper vias 93.

The second structure ST2 may include a lower insulating structure 23, a first interlayer insulating layer 57 stacked in order on the lower insulating structure 23, a first barrier insulating layer 63, a second interlayer insulating layer 66, a second barrier insulating layer 75, a third interlayer insulating layer 78, a third barrier insulating layer 86, a fourth interlayer insulating layer 88 and a fourth barrier insulating layer 90. The first to fourth barrier insulating layers 63, 75, 86, and 90 may include a material different from the material of interlayer insulating layers 23, 66, 78, and 88 between the first to fourth layers. The first peripheral interconnection structure RT2 may be disposed in the lower insulating structure 23. The second peripheral interconnection structure RT3 may be disposed in the first interlayer insulating layer 57, the first barrier insulating layer 63, the second interlayer insulating layer 66, the second barrier insulating layer 75 and the third interlayer insulating layer 78. The upper vias 93 may penetrate the third barrier insulating layer 86, the fourth interlayer insulating layer 88, and the fourth barrier insulating layer 90. The upper interconnections 96 may be disposed on the fourth barrier insulating layer 90.

Each of the routing lower structure RT1, the first peripheral interconnection structure RT2, the second peripheral interconnection structure RT3, the upper vias 93 and the upper interconnections 96 may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or a combination thereof, but an example embodiment thereof is not limited thereto. Each of the routing lower structure RT1, the first peripheral interconnection structure RT2, the second peripheral interconnection structure RT3, the upper vias 93 and the upper interconnections 96 may include a single layer or multiple layers formed of the above-described materials.

The second peripheral interconnection structure RT3 may include a conductive material different from at least one of the routing lower structure RT1, the first peripheral interconnection structure RT2, the upper vias 93 and the upper interconnections 96. At least a portion of the routing lower structure RT1 may include a first conductive material, at least a portion of the first peripheral interconnection structure RT2 may include a second conductive material, at least a portion of the second peripheral interconnection structure RT3 may include a third conductive material, the upper vias 93 may include a fourth conductive material, and the upper interconnections 96 may include a fifth conductive material. The third conductive material may include copper, and at least one of the routing lower structure RT1, the first peripheral interconnection structure RT2, the upper vias 93 and the upper interconnections 96 may not include copper. The fifth conductive material may include a material different from the first, second, third and fourth conductive materials, for example, aluminum, and at least one of the first, second and fourth conductive materials may include tungsten or molybdenum.

The second structure ST2 may further include a backside insulating layer 31 covering a lower surface of the semiconductor body 3 and lower surfaces of the through-insulating patterns 9.

A lower surface of the backside insulating layer 31 may be bonded to an upper surface of the fifth insulating structure 180. Accordingly, an upper surface of the first structure ST1 and an lower surface of the second structure ST2 may be bonded to each other, thereby forming a bonding surface JC.

The first and second structures ST1 and ST2 may further include through-vias 37 in (e.g., penetrating) the through-insulating patterns 9. The through-vias 37 may penetrate the through-insulating patterns 9, may extend upwardly, may be connected to the first peripheral interconnection structure RT2, may penetrate the through-insulating patterns 9, may extend downwardly and may be connected to the routing lower structure RT1.

Each of the through-vias 37 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or a combination thereof, but an example embodiment thereof is not limited thereto. Each of the through-vias 37 may include a single layer or multiple layers formed of the above-described conductive materials. For example, each of the through-vias 37 may include a conductive pillar 37b and a conductive barrier layer 37a covering a side surface and a lower surface of the conductive pillar 37b.

The word line WL may be electrically connected to the first peripheral transistor PTRw by the word line signal path WSP. Among the bit lines BL, the first bit line (BL1 in FIG. 2C) may be electrically connected to the second peripheral transistor PTRb1 by the first bit line signal path BL1SP. Among the bit lines BL, the second bit line (BL2 in FIG. 2C) may be electrically connected to the third peripheral transistor PTRb2 by the second bit line signal path BL2SP. The second electrode 131 of the data storage structure DS may be electrically connected to the fourth peripheral transistor PTRc included in a voltage supply circuit among the peripheral transistors PTR by a capacitor electrode signal path CPSP.

The routing lower structure RT1 may include a word line routing lower structure RT1w included in the word line signal path WSP, a first bit line routing lower structure RT1b1 included in the first bit line signal path BL1SP, and a capacitor electrode routing lower structure RT1c included in the capacitor electrode signal path CPSP.

The through-vias 37 may include a word line routing through-via 37w included in the word line signal path WSP, a first bit line routing through-via 37b1 included in the first bit line signal path BL1SP, a second bit line routing through-via 37b2 included in the second bit line signal path BL2SP, and a capacitor electrode routing through-via 37c included in the capacitor electrode signal path CPSP.

The first peripheral interconnection structure RT2 may include first routing peripheral structures RT2w, RT2b1, RT2b2, and RT2c. The first routing peripheral structures RT2w, RT2b1, RT2b2, and RT2c may include a word line routing peripheral structure RT2w included in a word line signal path WSP, a first bit line routing peripheral structure RT2b1 included in the first bit line signal path BL1SP, a second bit line routing peripheral structure RT2b2 included in the second bit line signal path BL2SP, and a capacitor electrode routing peripheral structure TR2c included in the capacitor electrode signal path CPSP.

The word line signal path (WSP in FIG. 3C) may include the word line contact WLC connected to (e.g., in contact with) the word line WL, the word line routing lower structure RT1w connected to the word line contact WLC, the word line routing lower structure RT1w connected to the word line contact WLC, a word line routing connection structure electrically connecting the word line routing lower structure RT1w to the word line routing peripheral structure RT2w, and a word line routing peripheral structure RT2w connecting the word line routing through-via 37w to the first peripheral transistor PTRw. The word line routing connection structure may include the word line routing through-via 37w vertically overlapping the memory block region CA and extending in (e.g., penetrating) the semiconductor body 3.

The word line contact WLC may be disposed in the first extension region ER1, and may electrically connect the word line WL to the word line routing lower structure RT1w in the first extension region ER1.

The word line routing lower structure (RT1w in FIG. 3C) may extend from the second extension region ER1 into the memory block region CA. The word line routing lower structure RT1w may include a word line routing lower redistribution line 160w connected to the word line contact WLC among the first horizontal portions 160, word line routing upper redistribution line 170w connected to the word line routing through-via 37w among the second horizontal portions 170, and a word line routing lower via 165w electrically connecting the word line routing lower redistribution line 160w to the word line routing upper redistribution line 170w between the word line routing lower redistribution line 160w and the word line routing upper redistribution line 170w among the vertical vias 165. Accordingly, the word line routing lower structure RT1w may include at least two redistribution lines 160w and 170w disposed at different vertical levels (i.e., different positions in the direction Z) from each other. The redistribution lines 160w and 170w may be configured as word line redistribution lines.

The word line routing through-via 37w may vertically overlap the memory block region CA. The word line routing through-via 37w may vertically overlap the data storage structure DS. A lower surface of the word line routing through-via 37w may be connected to the second horizontal portion 170w of the word line routing lower structure RT1w, and an upper surface of the word line routing through-via 37w may be connected to (e.g., in contact with) the word line routing peripheral structure RT2w. The word line routing through-via 37w may penetrate (e.g., extend through) the first through-insulating pattern 9_1 among the through-insulating patterns 9, and may be spaced apart from the semiconductor body 3 by the first through-insulating pattern 9_1.

The word line routing peripheral structure (RT2w in FIG. 3C) may include a first peripheral routing contact plug 15w connected to the first peripheral transistor PTRw among the vertical plugs 15, a first peripheral routing lower interconnection line 18w connected to the first peripheral routing contact plug 15w among the first horizontal portions 18, a first peripheral routing via 34w connected to the first peripheral routing lower interconnection line 18w among the first vertical vias 34, and a first peripheral routing upper interconnection line 45w electrically connecting the first peripheral routing via 34w to the word line routing through-via 37w among the second horizontal portions 45. An upper surface of the word line routing through-via 37w may be connected to a lower surface of the first peripheral routing upper interconnection line 45w. The word line routing peripheral structure RT2w may include at least two horizontal portions 18w and 45w disposed at different vertical levels from each other.

An upper surface of the word line routing through-via 37w may be connected in contact with a lower surface of the second peripheral routing upper interconnection 45w.

The first bit line signal path (BL1SP in FIG. 4C) may include the first bit line contact BL1C electrically connected to (e.g., in contact with) the first bit line BL1, the first bit line routing lower structure RT1b1 electrically connected to the first bit line contact BL1C, a first bit line routing connection structure 37b1 electrically connecting the first bit line routing lower structure RT1b1 to the first bit line routing peripheral structure RT2b1, and the first bit line routing peripheral structure RT2b1 electrically connecting the first bit line routing connection structure 37b1 to the second peripheral transistor PTRb1. The first bit line BL1 may cross the first memory block region CA1 and may extend into the second extension region ER2. The first bit line routing connection structure 37b1 may include the first bit line routing through-via 37b1.

The first bit line contact BL1C may be disposed in the second extension region ER2, and the first bit line BL1 and the first bit line routing lower structure RT1b1 may be electrically connected to (e.g., in contact with) each other in the second extension region ER2.

The first bit line routing lower structure (RT1b1 in FIG. 4C) may extend from the second extension region ER2 into the first memory block region CA1. The first bit line routing lower structure RT1b1 may include the first bit line routing lower redistribution line 160b1 connected to the first bit line contact BL1C among the first horizontal portions 160, a first bit line routing upper redistribution line 170b1 connected to the first bit line routing through-via 37b1 among the second horizontal portions 170, a first bit line routing lower via 165b1 electrically connecting the first bit line routing lower to upper redistribution lines 160b1 and 170b1 between the first bit line routing lower redistribution line 160b1 and the first bit line routing upper redistribution line 170b1 among the vertical vias 165. Accordingly, the first bit line routing lower structure RT1b1 may include at least two redistribution lines 160b1 and 170b1 disposed at different vertical levels from each other.

The first bit line routing through-via 37b1 may vertically overlap the first memory block region CA1. The first bit line routing through-via 37b1 may vertically overlap the data storage structure DS. A lower surface of the first bit line routing through-via 37b1 may be connected to the first bit line routing upper redistribution line 170b1 of the first bit line routing lower structure RT1b1 in the first memory block region CA1, and an upper surface of the first bit line routing through-via 37b1 may be connected to the first bit line routing peripheral structure RT2b1. The first bit line routing through-via 37b1 may penetrate (e.g., extend through) the second through-insulating pattern 9_2 among the through-insulating patterns 9, and may be spaced apart from the semiconductor body 3 by the second through-insulating pattern 9_2.

The first bit line routing peripheral structure RT2b1 may include a vertical plug 15b1 connected to the second peripheral transistor PTRb1, a first horizontal portion 18b1 on the vertical plug 15b1, a first vertical via 34b1 on the first horizontal portion 18b1, and a second horizontal portion 45b1 electrically connecting the first vertical via 34b1 to the first bit line routing through-via 37b1. An upper surface of the first bit line routing through-via 37b1 may be connected to a lower surface of the second horizontal portion 45b1. The first bit line routing peripheral structure RT2b1 may include at least two horizontal portions 18b1 and 45b1 disposed at different vertical levels from each other.

The second bit line signal path (BL2SP in FIG. 4D) may include the second bit line contact BL2C connected to the second bit line BL2, the second bit line routing lower structure RT1b2 connected to the second bit line contact BL2C, the second bit line routing lower structure RT1b2 connected to the second bit line contact BL2C, and the second bit line routing through-via 37b2 connected to the second bit line routing lower structure RT1b2, and the second bit line routing peripheral structure RT2b2 connecting the second bit line routing through-via 37b2 to the third peripheral transistor PTRb2. The second bit line BL2 may cross the first memory block region CA1 and the second memory block region CA2 adjacent to each other in the second direction Y and may extend into the second extension region ER2.

The second bit line contact BL2C may be disposed in the second extension region ER2, and the second bit line BL2 and the second bit line routing lower structure RT1b2 may be electrically connected to each other in the second extension region ER2.

The second bit line routing lower structure (RT1b2 in FIG. 4C) may include a second bit line routing lower redistribution line 160b2 connected to the second bit line contact BL2C, a second bit line routing upper redistribution line 170b2 connected to the second bit line routing through-via 37b2, and a second bit line routing lower via 165b2 electrically connecting the redistribution lines 160b2 and 170b2 to each other between the second bit line routing lower redistribution line 160b2 and the second bit line routing upper redistribution line 170b2. Accordingly, the second bit line routing lower structure RT1b2 may include at least two redistribution lines 160b2 and 170b2 disposed at different vertical levels from each other.

The second bit line routing through-via 37b2 may vertically overlap the second extension region ER2. A lower surface of the second bit line routing through-via 37b2 may be connected to the second bit line routing upper redistribution line 170b2 of the second bit line routing lower structure RT1b2 in the second extension region ER2, and an upper surface of the second bit line routing through-via 37b2 may be connected to the second bit line routing peripheral structure RT2b2. The second bit line routing through-via 37b2 may penetrate the third through-insulating pattern 93 among the through-insulating patterns 9, and may be spaced apart from the semiconductor body 3 by the third through-insulating pattern 9_3. The second bit line routing through-via 37b2 may be electrically connected to the third peripheral transistor PTRb2 vertically overlapping the first memory block region CA1, and the second bit line routing through-via 37b2 may not vertically overlap the first memory block region CA1. The first to third peripheral transistors PTRw, pTRb1, and pTRb2 may vertically overlap the first memory block region CA1.

The second bit line routing peripheral structure RT2b2 may include a vertical plug 15b2 connected to the third peripheral transistor PTRb2, a first horizontal portion 18b2 on the vertical plug 15b2, a first vertical via 34b2 on the first horizontal portion 18b2, a 2-1 horizontal portion 45b2b on the first vertical via 34b2, a 3-1 vertical via 48b2b on the 2-1 horizontal portion 45b2b, a 2-2 horizontal portion 45b2a on the second bit line routing through-via 37b2, a 3-2 vertical via 48b2a on the 2-2 horizontal portion 45b2a, and a third horizontal portion 51b2 connecting the 3-2 vertical via 48b2a to the 3-1 vertical via 48b2b. An upper surface of the second bit line routing through-via 37b2 may be connected to a lower surface of the second horizontal portion 45b2a. The second bit line routing peripheral structure RT2b2 may include at least three horizontal portions 18b2, 45b2b, and 51b2 disposed at different vertical levels from each other.

In the description below, various modified examples of elements of an example embodiment described above will be described. Various modified examples of the elements of the above-described example embodiment described below will be described with respect to modified or replaced elements. Here, the elements described above may be quoted directly without detailed description, or the description may not be provided. Also, the elements which may be modified or replaced will be described with reference to the drawings, but the elements which may be modified or replaced may be combined with each other or with the elements described above and may be included in the semiconductor device according to an example embodiment.

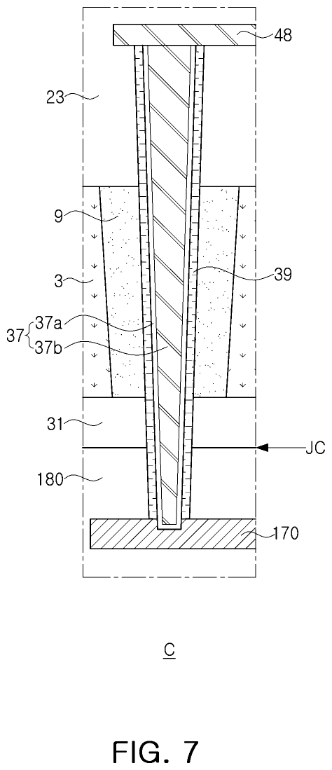

FIG. 7 is a diagram illustrating an enlarged example of region “C” in FIG. 3A to describe an example of a semiconductor device according to an example embodiment.

Referring to FIG. 7, an insulating spacer 39 may be disposed on a side surface of the through-via 37. The insulating spacer 39 may be disposed between the fifth insulating structure 180 and the through-via 37, between the backside insulating layer 31 and the through-via 37, between the through-insulating pattern 9 and the through-via 37, and between the lower insulating structure 23 and the through-via 37. A lower end of the insulating spacer 39 may be disposed at a level lower than a level of a lower surface of the through-insulating pattern 9, and an upper end of the insulating spacer 39 may be disposed at a level higher than a level of an upper surface of the through-insulating pattern 9.

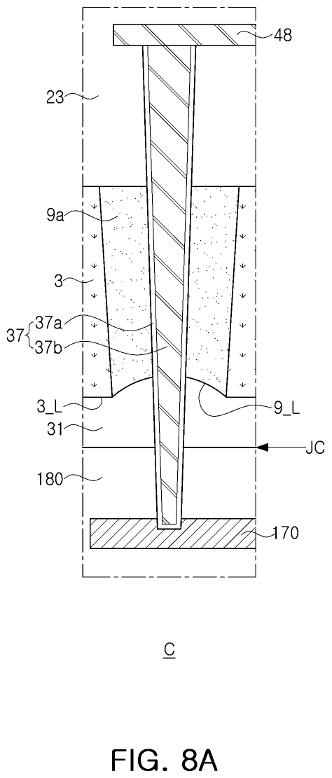

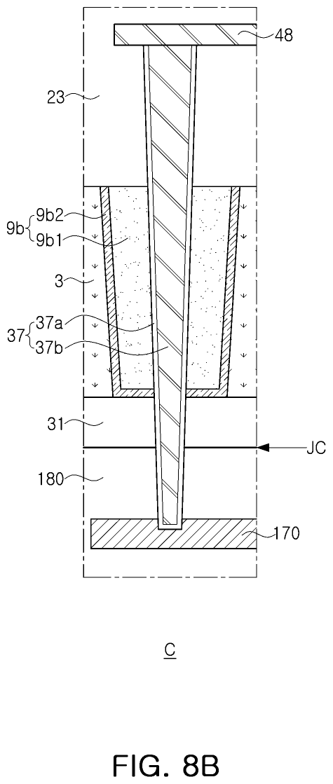

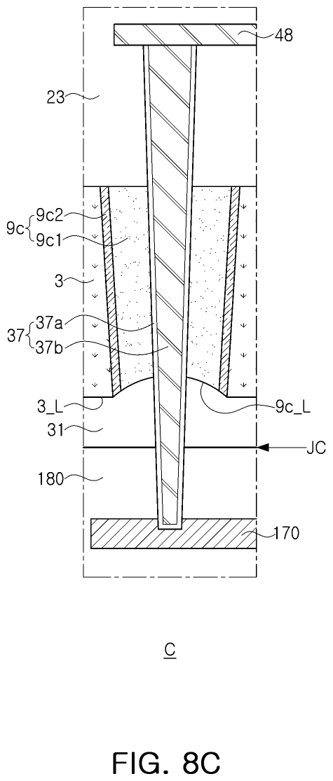

FIG. 8A is a diagram illustrating an enlarged example of region “C” in FIG. 3A to describe an example of a semiconductor device according to an example embodiment.

Referring to FIG. 8A, a through-insulating pattern 9 described above may be replaced with a through-insulating pattern 9a of which a lower surface may have a lower surface 9_L having an upwardly curved shape. The lower surface 9_L of the through-insulating pattern 9a may be further recessed than the lower surface 3_L of the semiconductor body 3. A lower surface 9_L of the through-insulating pattern 9a and a lower surface 3_L of the semiconductor body 3 may be in contact with a backside insulating layer 31.

FIG. 8B is a diagram illustrating an enlarged example of region “C” in FIG. 3A to describe an example of a semiconductor device according to an example embodiment.

Referring to FIG. 8B, a through-insulating pattern 9 described above may be replaced with a through-insulating pattern 9b including at least two insulating layers. For example, the through-insulating pattern 9b may include an insulating pillar 9b1 and an insulating liner 9b2 covering a side surface and a lower surface of the insulating pillar 9b1. The insulating pillar 9b1 and the insulating liner 9b2 may be formed of different materials. The insulating liner 9b2 may be in contact with the backside insulating layer 31, and the insulating pillar 9b1 may be spaced apart from the backside insulating layer 31.

FIG. 8C is a diagram illustrating an enlarged example of region “C” in FIG. 3A to describe an example of a semiconductor device according to an example embodiment.

Referring to FIG. 8C, the through-insulating pattern 9 described above may be replaced with through-insulating pattern 9c having a lower surface 9c_L having an upwardly curved shape including at least two insulating layers. The lower surface 9c_L of the through-insulating pattern 9c may be recessed upwardly more than the lower surface 3_L of the semiconductor body 3. The through-insulating pattern 9c may include an insulating pillar 9c1 and an insulating liner 9c2 between a side surface of the insulating pillar 9c1 and the semiconductor body 3. The insulating pillar 9c1 and the insulating liner 9c2 may be formed of different materials. A lower surface of the insulating pillar 9c1 may be in contact with the backside insulating layer 31.

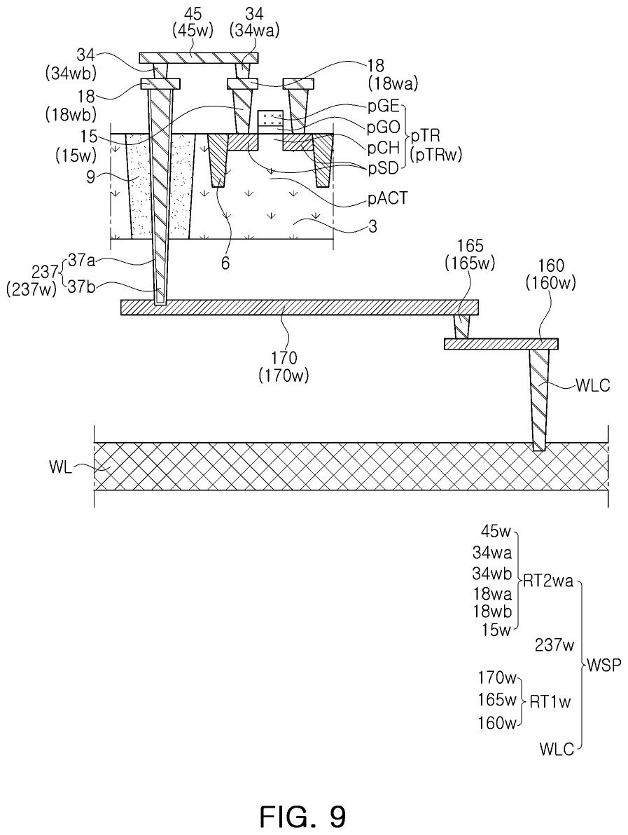

FIG. 9 is a cross-sectional diagram illustrating an example of a semiconductor device according to an example embodiment, illustrating a portion modified from the cross-sectional diagram in FIG. 3A.

Referring to FIG. 9, the through-vias 37 disposed at a level higher than a level of the first horizontal portions 18 in FIGS. 3A to 8C may be replaced with through-vias 237 disposed at a level lower than a level of the first horizontal portions 18. The through-vias 237 and the first horizontal portions 18 may include through-vias 237 and first horizontal portions 18 in contact with each other.

The through-vias 237 may include a word line routing through-via 237w included in the word line signal path WSP. The first peripheral interconnection structure RT2 may include a word line routing peripheral structure RT2wa included in the word line signal path WSP.

The lower surface of the word line routing through-via 237w may be connected to the second horizontal portion 170w of the word line routing lower structure RT1w, and an upper surface of the word line routing through-via 237w may be connected to the word line routing peripheral structure RT2wa.

The word line routing peripheral structure RT2wa may include a vertical plug 15w connected to the first peripheral transistor PTRw, a first horizontal portion 18wa on the vertical plug 15w, a 2-1 vertical via 34wa on the 1-1 horizontal portion 18wa, a 1-2 horizontal portion 18wb connected to an upper surface of the word line routing through-via 237w, a 2-2 vertical via 34wb on the 1-2 horizontal portion 18wb, and a second horizontal portion 45w electrically connecting the 2-1 vertical via 34wa to the 2-2 vertical via 34wb. An upper surface of the word line routing through-via 237w may be connected to a lower surface of the 1-2 horizontal portion 18wa. The word line routing through-via 237w may be connected to the horizontal portion 18wb disposed at a level lower than a level of the word line routing peripheral structure RT2w.

According to an example embodiment, in the word line routing peripheral structure RT2wa, the first horizontal portion 18wa and the 1-2 horizontal portion 18wb may be integrated with each other and may form a word line routing interconnection, and the 2-1 vertical via 34wa, the 2-1 vertical via 34wa, and the second horizontal portion 45w may not be provided. Accordingly, the word line routing peripheral structure RT2wa may include a word line routing interconnection 18wa and 18wb in contact with and connected to an upper surface of the word line routing through-via 237w.

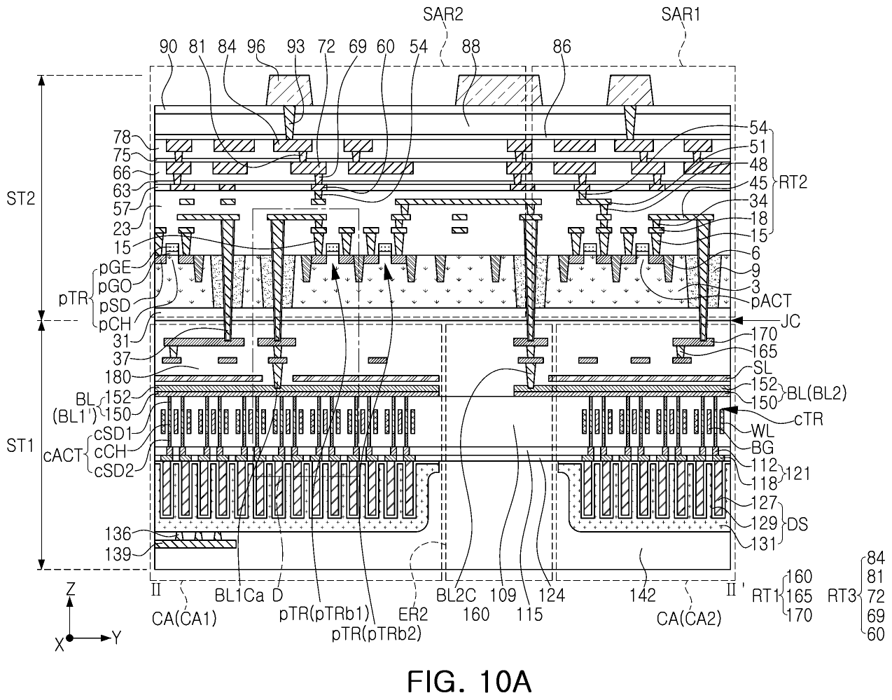

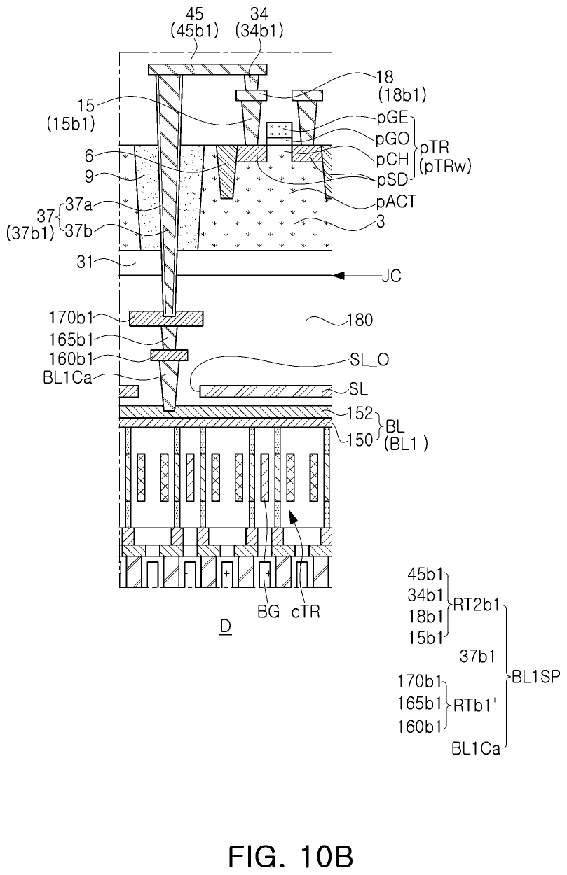

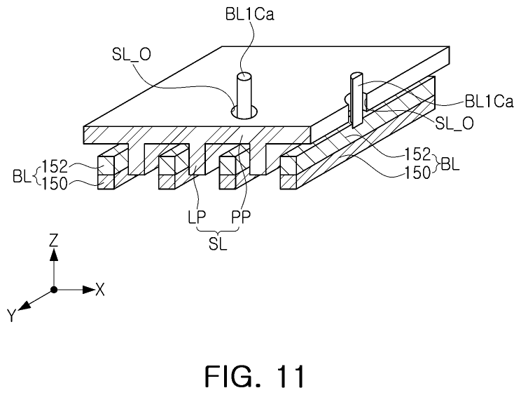

An example of a semiconductor device according to an example embodiment will be described with reference to FIGS. 10A, 10B and 11. FIG. 10A is a cross-sectional diagram illustrating a region taken along line II-II′ in FIG. 1B. FIG. 10B is an enlarged diagram illustrating region “D” in FIG. 10A. FIG. 11 is a perspective diagram illustrating a portion of a first bit line signal path BL1SP, first bit lines BL, and conductive shield structure SL in a semiconductor device according to an example embodiment.

Referring to FIGS. 10A, 10B and 11, the first bit line contact (BL1C in FIG. 4A) connected to (e.g., in contact with) the first bit line BL1 in the second extension region ER2 in FIGS. 3A to 9 may be replaced with the first bit line contact BL1Ca penetrating the conductive shield structure SL and connected to (e.g., in contact with) the first bit line BL1 in the first memory cell block region CA1. As a length of the first bit line BL1 extending into the second extension region ER2 may be reduced, a width of the second extension region ER2 may be reduced. Accordingly, integration density of the semiconductor device may be increased.

The conductive shield structure SL may have an opening SL_O penetrating the connection portion PP of the conductive shield structure SL. The first bit line contact BL1Ca may pass the opening SL_O, may be in contact with and connected to the first bit line BL1.

The first bit line routing lower structure (RT1b1 in FIG. 4c) described above may be replaced with a first bit line routing lower structure RT1b1′ connected to the first bit line contact BL1Ca.

The first bit line signal path BL1SP may include the first bit line contact BL1Ca, the first bit line routing lower structure RT1b1′, the first bit line routing through-via 37b1, and the first bit line routing peripheral structure RT2b1.

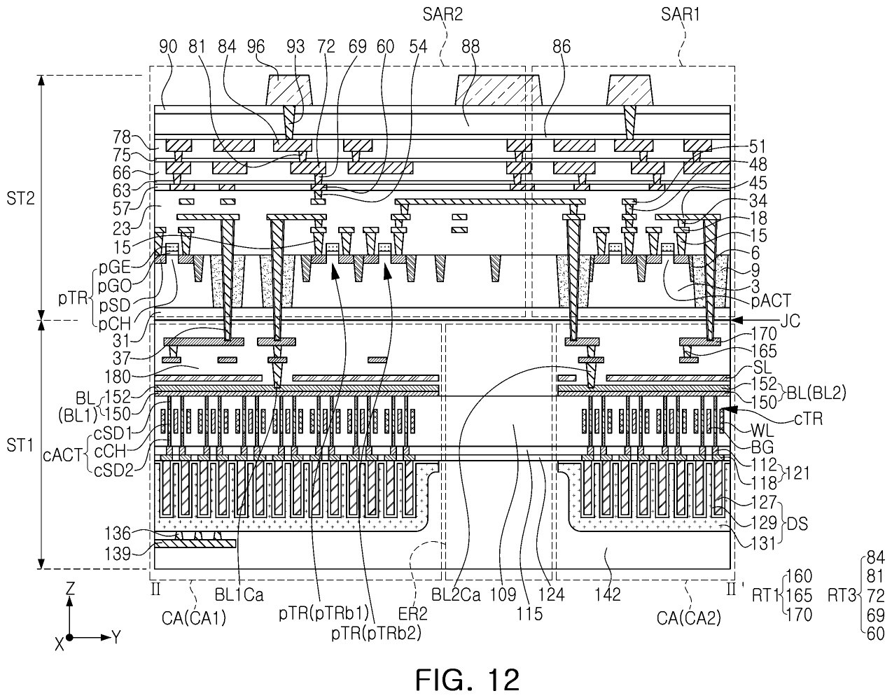

An example of a semiconductor device according to an example embodiment will be described with reference to FIG. 12. FIG. 12 is a cross-sectional diagram illustrating region taken along line II-II′ in FIG. 1B.

Referring to FIG. 12, the second bit line contact (BL2C in FIG. 4A) connected to the second bit line BL2 in the second extension region ER2 in FIGS. 3A to 11 may be replaced with a second bit line contact BL2Ca penetrating the conductive shield structure SL and is connected to the second bit line BL2 in the second memory cell block region CA2. As a length of the second bit line BL2 extending into the second extension region ER2 may be reduced, a width of the second extension region ER2 may be reduced. Accordingly, integration density of the semiconductor device may increase.

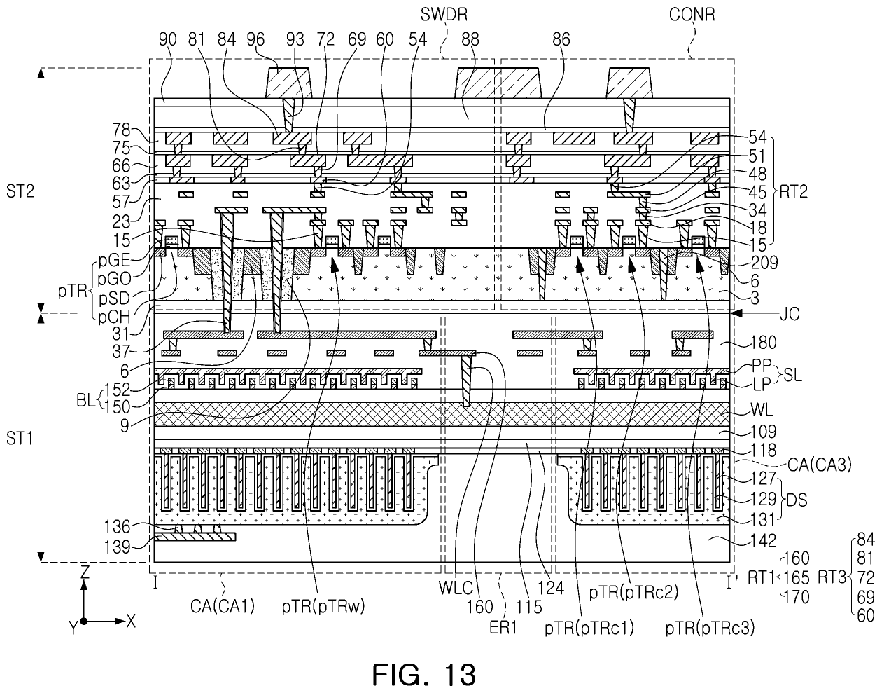

An example of a semiconductor device according to an example embodiment will be described with reference to FIG. 13. FIG. 13 is a cross-sectional diagram illustrating a region taken along line I-I′ in FIG. 1B.

Referring to FIG. 13, a second structure ST2 in FIGS. 3A to 12 may further include a device isolation insulating pattern 209 penetrating the semiconductor body 3. The device isolation insulating pattern 209 may be formed by the same semiconductor process as the through-insulating patterns 9. Accordingly, the device isolation insulating pattern 209 may have the same shape as that of the through-insulating patterns 9.

In an example, the device isolation insulating pattern 209 may penetrate the isolation region 6, may extend downwardly and may penetrate the semiconductor body 3.

In an example, the through-insulating patterns 9 may penetrate the isolation region 6, may extend downwardly and may penetrate the semiconductor body 3.

In an example, the peripheral transistors PTR may include fourth and fifth peripheral transistors pTRc1, pTRc2 spaced apart from each other by the isolation region 6, and fifth and sixth peripheral transistors pTRc2, pTRc3 spaced apart from each other by the device isolation insulating pattern 209. One of the fifth and sixth peripheral transistors pTRc2 and pTRc3 may be configured as an NMOS transistor, and the other may be configured as a PMOS transistor. In another example, one of the fifth and sixth peripheral transistors pTRc2 and pTRc3 may be a transistor included in a first circuit, and the other may be a transistor included in a second circuit different from the first circuit. Accordingly, the device isolation insulating pattern 209 may also isolate different circuits from each other.

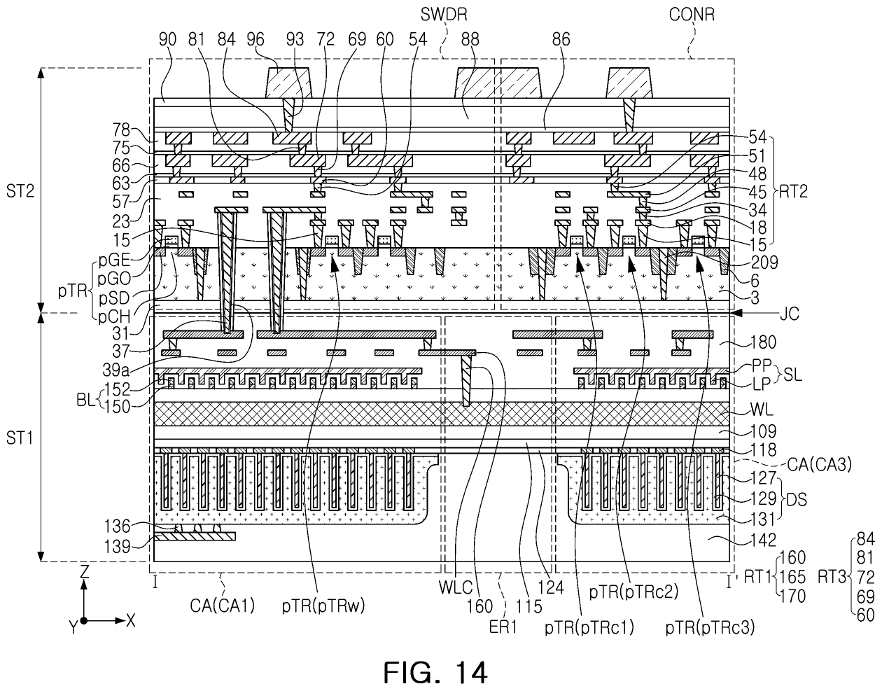

An example of a semiconductor device according to an example embodiment will be described with reference to FIG. 14. FIG. 14 is a cross-sectional diagram illustrating a region taken along line I-I′ in FIG. 1B.

Referring to FIG. 14, the through-insulating patterns 9 in FIGS. 3A to 13 may not be provided, and the through-via 37 in FIGS. 3A to 13 may penetrate the semiconductor body 3. The second structure ST2 may include the same insulating spacer 39a as the insulating spacer 39 in FIG. 7. The insulating spacer 39a may be disposed on a side surface of the through-via 37 and may isolate the through-via 37 from the semiconductor body 3.

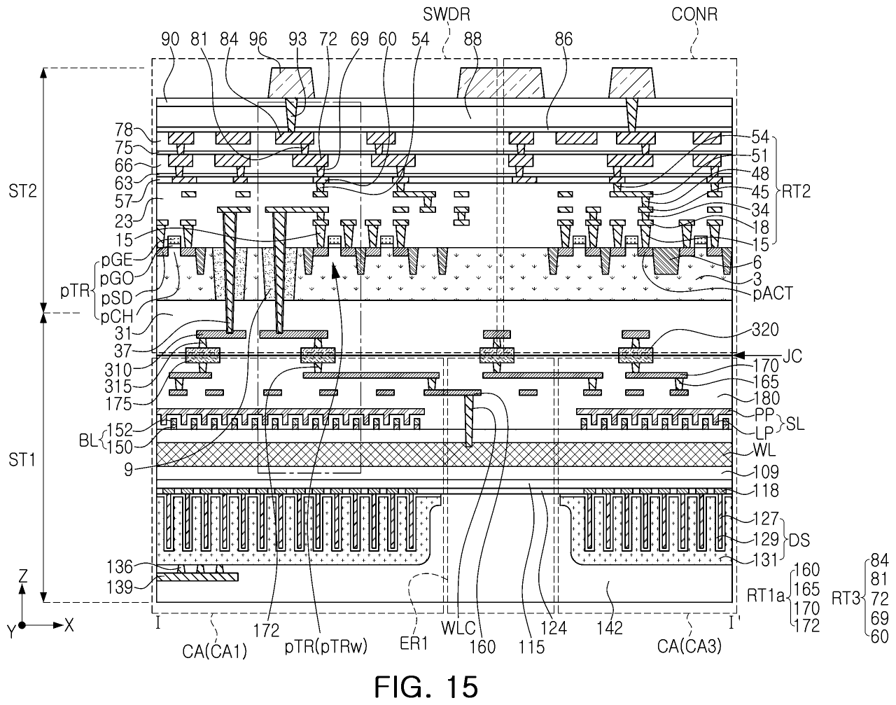

An example of a semiconductor device according to an example embodiment will be described with reference to FIG. 15. FIG. 15 is a cross-sectional diagram illustrating a region taken along line I-I′ in FIG. 1B.

Referring to FIG. 15, the first structure ST1 in FIGS. 3A to 14 may further include first bonding pads 175 having an upper surface coplanar with an upper surface of the fifth insulating structure 180. The routing lower structure RT1 in FIGS. 3A to 14 may be replaced with a lower routing structure RT1a further including first connection vias 172 connecting the first bonding pads 175 to the second horizontal portions 170.

The second structure ST2 in FIGS. 3A to 14 may have a lower surface coplanar with a lower surface of the backside insulating layer 31, and may further include second bonding pads 320 in contact with and bonded to the first bonding pads 175 and redistribution line structures 310 and 315 connecting the second bonding pads 320 to the through-vias 37. The redistribution line structures 310 and 315 may include redistribution lines 310 connected to the through-vias 37, and second connection vias 315 connecting the redistribution lines 310 to the second bonding pads 320. The first and second bonding pads 175 and 320 may include the same metal material, for example, copper. The word line routing connection structure may include the first bonding pad 175 electrically connected to the word line routing lower structure (RT1w in FIG. 3C), the redistribution line structure 310 and 315 electrically connected to the word line routing through-via (37w in FIG. 3C), and the second bonding pad 320, in addition to the word line routing through-via (37w in FIG. 3C).

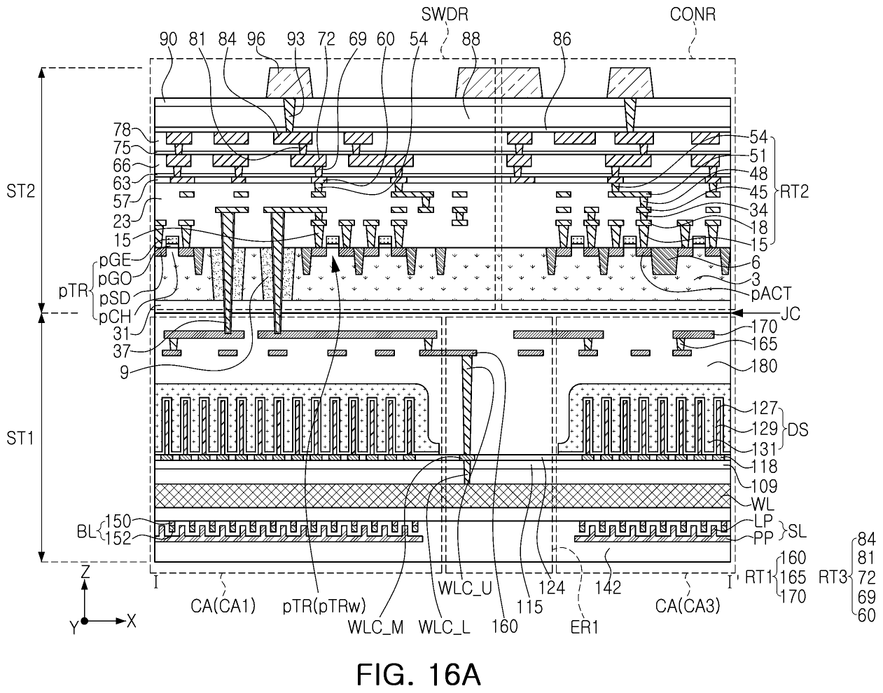

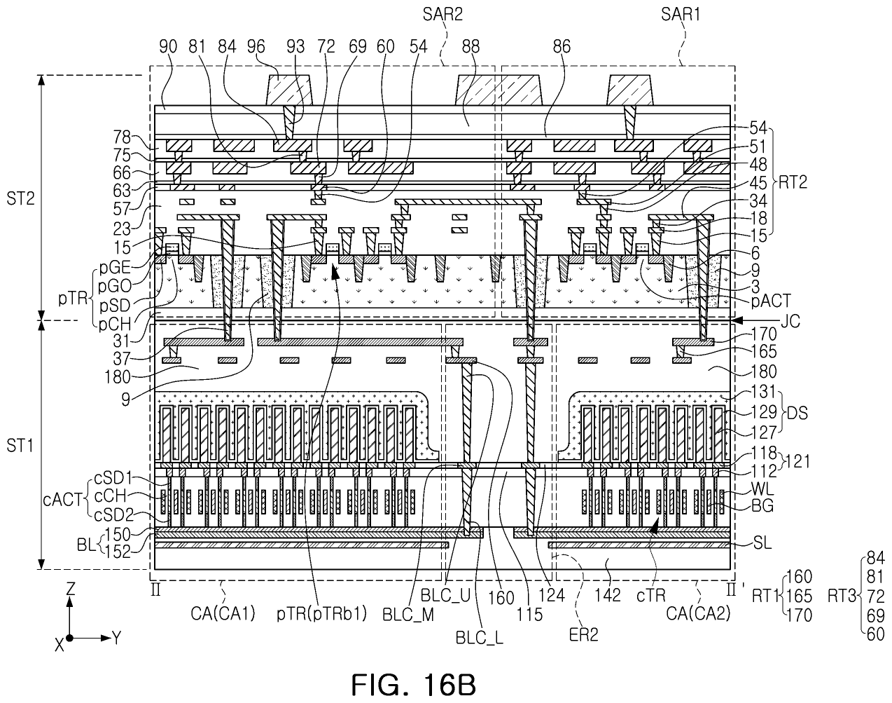

An example of a semiconductor device according to an example embodiment will be described with reference to FIGS. 16A and 16B. FIG. 16A is a cross-sectional diagram illustrating a region taken along line I-I′ in FIG. 1B, and FIG. 16B is a cross-sectional diagram illustrating a region taken along line II-II′ in FIG. 1B.

Referring to FIGS. 16A and 16B, a structure including the data storage structure DS and the conductive shield structure SL (and layers/elements therebetween) in FIGS. 3A to 15 may be modified to be disposed upside down. The bit lines BL may be modified to bit lines BL disposed at a level lower than a level of the word lines WL and the cell transistors cTR, and the data storage structure DS in FIGS. 3A to 15 may be modified to a data storage structure DS disposed at a level higher than a level of the word lines WL and the cell transistors cTR. The data storage structure DS may include first electrodes 127, a second electrode 131 having a side surface and an upper surface on the first electrodes 127, and the dielectric layer 129 between the first electrodes 127 and the second electrode 131.

In the contact structures 121 described above, the plug portions 112 may be connected to the cell transistors cTR, and the pad portions 118 may electrically connect the plug portions 12 to the first electrodes 127 between the plug portions 12 and the first electrodes 127.

In each of the bit lines BL, the second conductive layer 152 may be modified to be disposed below the first conductive layer 150. Accordingly, the first conductive layer 150 may be disposed on the second conductive layer 152.

The word line contact WLC in FIGS. 3A to 15 may be replaced with an upper word line contact WLC_U connected to the routing lower structure RT1 on a lower word line contact WLC_L connected to the word line WL in the first extension region ER1, an intermediate word line contact WLC_M on the lower word line contact WLC_L and an intermediate word line contact WLC_M. The intermediate word line contact WLC_M may be disposed at the same vertical level as a level of the pad portions 118.

Each of the bit line contacts BL1C and BL2C in FIGS. 3A to 15 may be replaced with an upper bit line contact BLC_U connected to the routing lower structure RT1 on a lower bit line contact BLC_L connected to the bit line BL in the second extension region ER2, an intermediate bit line contact BLC_M on the lower bit line contact C_L, and the intermediate bit line contact BLC_M. The intermediate bit line contact BLC_M may be disposed at the same vertical level as a level of the pad portions 118.

The lower bit line contact BLC_L may be in contact with the first conductive layer 150 and the second conductive layer 152 of the bit line BL. The lower bit line contact BLC_L may have a lower surface disposed at a level lower than a level of the lower surface of the first conductive layer 150 and may be in contact with the second conductive layer 152.

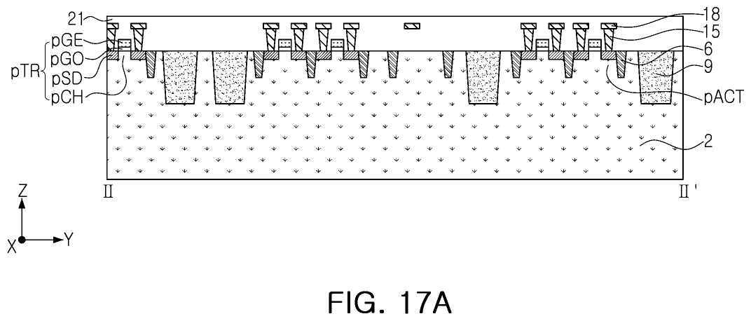

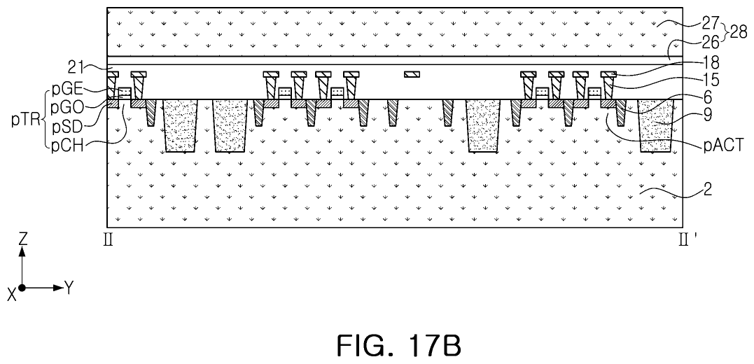

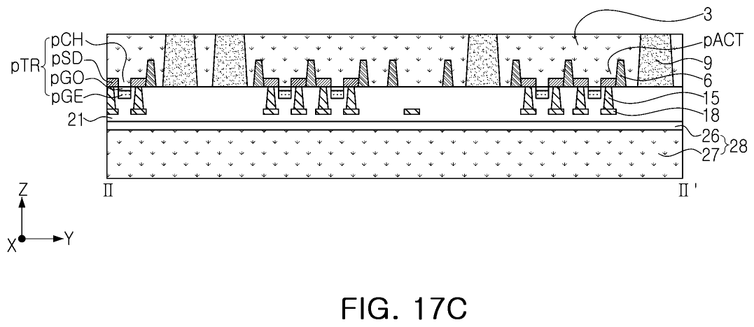

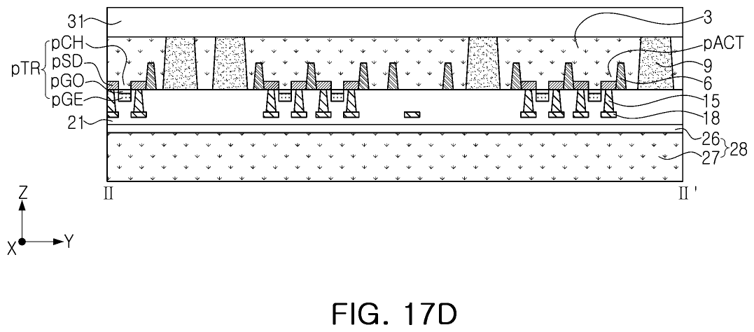

In the description below, an example of a method of manufacturing a semiconductor device according to an example embodiment will be described with reference to FIGS. 17A to 17D, 18A, 18B, and 19A to 19C. FIGS. 17A to 17D, 18A, 18B, and 19A to 19C are cross-sectional diagrams illustrating a region taken along line II-II′ in FIG. 1B, illustrating an example of a method of manufacturing a semiconductor device according to an example embodiment.

Referring to FIGS. 1B and 17A, an isolation region 6 defining peripheral active regions pACT may be formed on a substrate 2. Through-insulating patterns 9 may be formed on the substrate 2. Lower surfaces of the through-insulating patterns 9 may be formed at a vertical level lower than a level of a lower surface of the isolation region 6.

Peripheral transistors PTR may be formed on the substrate 2. Each of the peripheral transistors PTR may include peripheral source/drain regions pSD formed in the peripheral active region pACT, a peripheral channel region pCH between the peripheral source/drain regions pSD, and peripheral gates pGO and pGE on the peripheral channel region pCH. The peripheral gate pGO and pGE may include a peripheral gate dielectric layer pGO and a peripheral gate electrode pGE on the peripheral gate dielectric layer pGO.

By performing a first interconnection process on the substrate 2, vertical plugs 15 connected to the peripheral transistors PTR, first horizontal portions 18 on the vertical plugs 15, and an insulating structure 21 covering the vertical plugs 15 and the first horizontal portions 18 on the substrate 2 may be formed.

Referring to FIGS. 1B and 17B, a first support substrate 28 including a first adhesive layer 26 bonded to an upper surface of the insulating structure 21 and a first wafer 27 on the first adhesive layer 26 may be formed.

Referring to FIGS. 1B and 17C, the semiconductor body 3 may be formed by reducing a thickness of the substrate (2 in FIG. 17B) until the through-insulating patterns 9 are exposed. For example, by grinding the substrate (2 in FIG. 17B) supported by the support substrate 28, a semiconductor body 3 having a thickness less than that of the substrate (2 in FIG. 17B) may be formed. The semiconductor body 3 may be formed, and the through-insulating patterns 9 may be exposed. For example, in a grinding process for reducing a thickness of the substrate (2 in FIG. 17b), the through-insulating patterns 9 may work as a stopper.

In an example, to form through-insulating patterns 9a and 9c as illustrated in FIG. 8A or 8C, the exposed surface of the semiconductor body 3 and the exposed surface of the through-insulating patterns 9 may be cleaned, and surfaces of the through-insulating patterns 9 may also be recessed.

Referring to FIGS. 1B and 17D, a backside insulating layer 31 may be formed on the exposed surface of the semiconductor body 3 and the exposed surface of the through-insulating patterns 9. The exposed surface of the semiconductor body 3 and the exposed surface of the through-insulating patterns 9 may be in contact with the backside insulating layer 31.

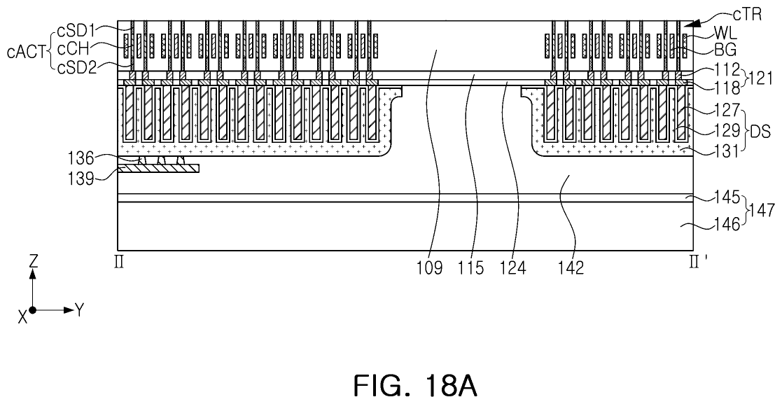

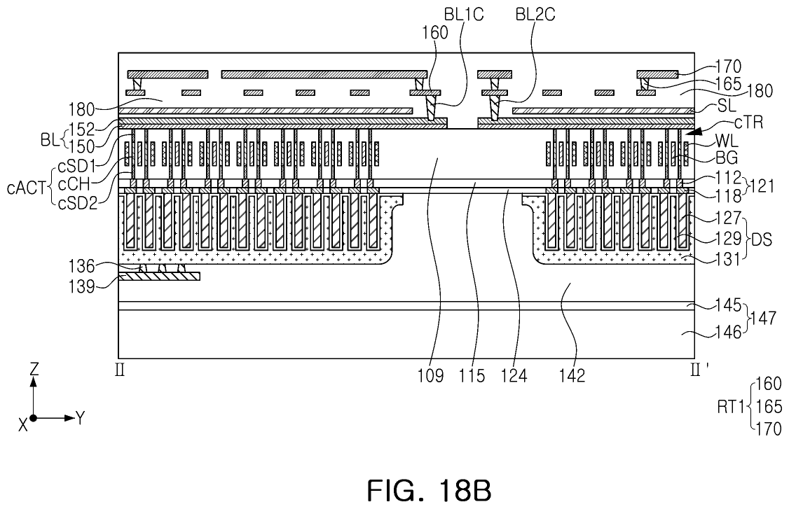

Referring to FIG. 18A, cell transistors cTR and back gate lines BG using word lines WL as gate electrodes may be formed using a silicon on insulator substrate (SOI substrate). The cell transistors cTR and the back gate lines BG may be buried in the insulating structure 142. The cell source/drain regions cSD1 and cSD2 and the vertical channel region cCH of each of the cell transistors cTR may be formed in the cell active pattern cACT. The cell active patterns cACT may be formed of silicon in the SOI substrate. Contact structures 121 and insulating layers 124 and 115 may be formed on the cell transistors cTR, data storage structures DS may be formed on the contact structures 121, capacitor via 136 and capacitor interconnection 139 may be formed on the data storage structures DS, and an insulating structure 142 covering the data storage structures DS, the capacitor via 136 and the capacitor interconnection 139 may be formed. A second support substrate 147 including a second adhesive layer 145 bonded to the insulating structure 142 and a second wafer 146 on the second adhesive layer 145 may be formed. By removing the insulating layer and the substrate in the SOI substrate, the cell active patterns cACT may be exposed.

Referring to FIG. 18B, bit lines BL connected to the first source/drain regions cSD1 of the cell active patterns aACT and a shield structure SL on the bit lines BL may be formed. As described above, the conductive shield structure SL may include line portions (LP in FIG. 5) between the bit lines BL and a connection portion (PP in FIG. 5) extending from the line portions LP and covering the bit lines BL. The conductive shield structure SL may be spaced apart from the bit lines BL by an insulating material.

Bit line contacts BL1C and BL2C connected to the bit lines BL and word line contacts (WLC in FIG. 3A) connected to the word lines WL may be formed.

A routing lower structure RT1 may be formed on the bit line contacts BL1C and BL2C and the word line contacts (WLC in FIG. 3A). Forming the routing lower structure RT1 may include forming first horizontal portions 160 on the bit line contacts BL1C and BL2C and the word line contacts (WLC in FIG. 3A), forming vertical vias 165 on the first horizontal portions 160, and forming second horizontal portions 170 on the vertical vias 165.

The bit line contacts BL1C and BL2C, the word line contacts (WLC in FIG. 3A), the first horizontal portions 160, the vertical vias 165 and the second horizontal portions 170 may be covered by the insulating structure 180.

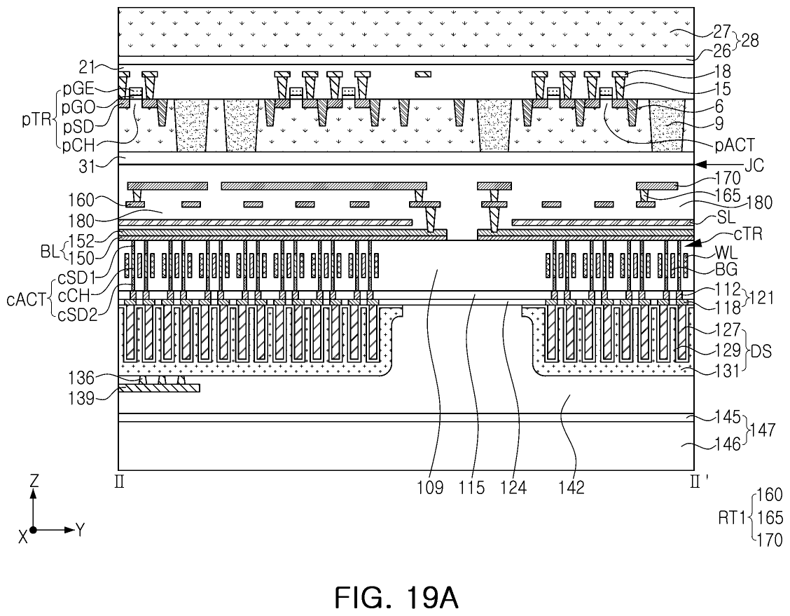

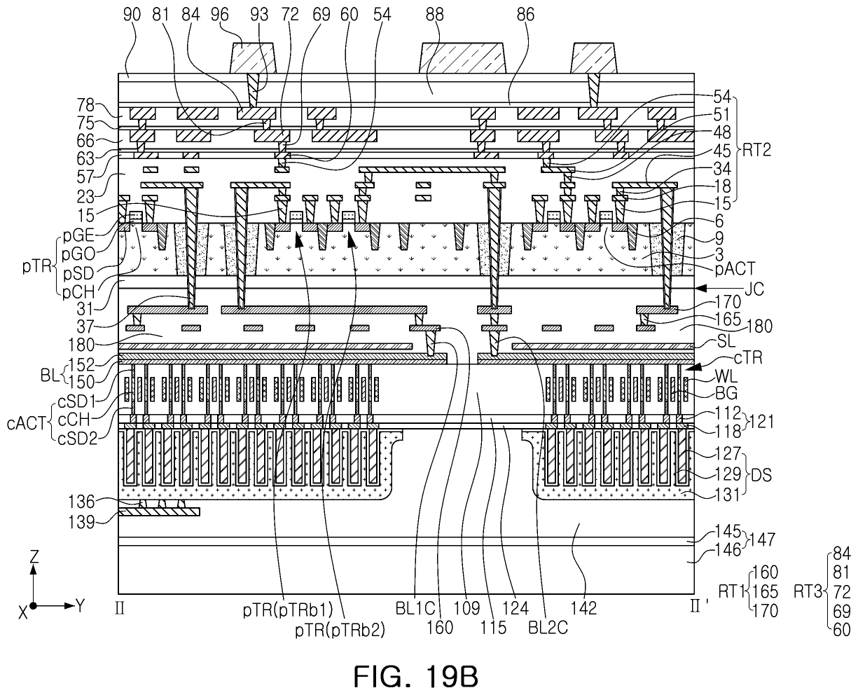

Referring to FIG. 19A, by performing a wafer bonding process, the insulating structure 180 supported by the second support substrate 147 and the backside insulating layer 31 supported by the first support substrate 28 may be in contact with and bonded to each other. A bonding surface JC may be formed as the insulating structure 180 and the backside insulating layer 31 are bonded to each other.

Referring to FIG. 19B, the first support substrate (28 in FIG. 19A) may be removed. First vertical vias 34 may be formed on the first horizontal portions 18. Through-vias 37 penetrating the insulating patterns 19 and connected to the second horizontal portions 170 of the routing lower structure RT1 may be formed.

In example embodiments, the first vertical vias 34 and the through-vias 37 may be formed simultaneously or may be formed in separate processes.

The second horizontal portions 45 on the first vertical vias 34 and the through-vias 37, second vertical vias 48 on the second horizontal portions 45, third horizontal portions 51 on the second vertical vias 48, and third vertical vias 54 on the third horizontal portions 51 may be formed. The vertical plugs 15, the first horizontal portions 18, the first vertical vias 34, the second horizontal portions 45, the second vertical vias 48, the third horizontal portions 51, and the third vertical vias 54 may be included in the first peripheral interconnection structure RT2. The first peripheral interconnection structure RT2 may be buried in the insulating structure 23.

A second peripheral interconnection structure RT3 and insulating layers 57, 63, 66, 75, and 78 covering side surfaces of the second peripheral interconnection structure RT3 may be formed on the first peripheral interconnection structure RT2.

The second peripheral interconnection structure RT3 may include first horizontal portions 60, first vertical vias 69 on the first horizontal portions 60, second horizontal portions 72 on the first vertical vias 69, third vertical vias 81 on the second horizontal portions 72, and fourth horizontal portions 84 on the third vertical vias 81.

The insulating layers 86, 88, and 90 stacked in order on the second peripheral interconnection structure RT3 may be formed, upper vias 93 penetrating the insulating layers 86, 88, and 90 may be formed, and upper interconnections 96 may be formed on the upper vias 93.

Thereafter, by removing the second support substrate 147, the semiconductor device 1 described in FIGS. 1A to 6 may be formed.

According to the aforementioned example embodiments, a semiconductor device including a memory block region and a peripheral circuit region vertically overlapping each other may be provided. Accordingly, integration density of the semiconductor device may increase.

Also, a word line may cross first and second memory block regions adjacent to each other and an extension region between the first and second memory block regions.

Also, a word line signal path electrically connecting the word line to the first peripheral transistor of the peripheral circuit region may be provided. The word line signal path may include a word line contact connected to the word line in the extension region, a word line routing lower structure extending from the extension region into the first memory block region, and a word line routing through-via penetrating the through-insulating pattern penetrating the semiconductor body in the peripheral circuit region. The word line routing through-via and the first peripheral transistor may vertically overlap the first memory block region. This arrangement of the word line signal path and the first peripheral transistor as above may increase integration density of the semiconductor device and may improve a signal transmission speed, thereby improving performance of the semiconductor device.

While the example embodiments have been illustrated and described above, it will be apparent to those skilled in the art that modifications and variations may be made without departing from the scope defined by the appended claims.

What is claimed is:

1. A semiconductor device comprising:
a first structure having a memory block region and an extension region adjacent to the memory block region in a first direction; and
a second structure vertically overlapping the first structure and having a peripheral circuit region vertically overlapping the memory block region,
wherein the first structure includes:
memory cells in the memory block region and each including a vertical channel transistor and a data storage structure; and
a word line electrically connected to the memory cells, intersecting the memory block region and extending into the extension region,
wherein the second structure includes:
a semiconductor body;
a backside insulating layer below the semiconductor body;
an isolation region defining peripheral active regions on the semiconductor body;
a through-insulating pattern in the semiconductor body; and
a peripheral transistor including a first peripheral source/drain, a second peripheral source/drain, a peripheral channel region between the first and second peripheral source/drains, and a peripheral gate on the peripheral channel region,
wherein the first and second peripheral source/drains and the peripheral channel region are in a first peripheral active region among the peripheral active regions,
wherein the first and second structures include a word line signal path electrically connecting the word line to the peripheral transistor,
wherein the word line signal path includes:
a word line routing peripheral structure electrically connected to the peripheral transistor and on the semiconductor body;
a word line contact that is in contact with the word line in the extension region;
a word line routing lower structure electrically connected to the word line contact and extending from the extension region into the memory block region; and
a word line routing connection structure electrically connecting the word line routing lower structure to the word line routing peripheral structure, and
wherein the word line routing connection structure includes a word line routing through-via vertically overlapping the memory block region and penetrating through the semiconductor body.

2. The semiconductor device of claim 1,
wherein the word line routing through-via penetrates through the through-insulating pattern,
wherein an upper surface of the word line routing through-via is at a level higher than a level of an upper surface of the semiconductor body and a level of an upper surface of the through-insulating pattern,
wherein a lower surface of the word line routing through-via is at a level lower than a level of a lower surface of the semiconductor body and a level of a lower surface of the through-insulating pattern, and
wherein the word line routing through-via is spaced apart from the semiconductor body by the through-insulating pattern.

3. The semiconductor device of claim 2,
wherein the second structure further includes an insulating spacer on a side surface of the word line routing through-via,
wherein a lower end of the insulating spacer is at a level lower than the level of the lower surface of the through-insulating pattern, and
wherein an upper end of the insulating spacer is at a level higher than the level of the upper surface of the through-insulating pattern.

4. The semiconductor device of claim 1, wherein the word line routing lower structure includes:
a word line routing lower redistribution line electrically connected to the word line contact;
a word line routing lower via on the word line routing lower redistribution line; and
a word line routing upper redistribution line electrically connecting the word line routing lower via to the word line routing through-via.

5. The semiconductor device of claim 1, wherein the vertical channel transistor includes:
a first cell source/drain region, a second cell source/drain region at a level different from a level of the first cell source/drain region, and a vertical channel region between the first and second cell source/drain regions, wherein the vertical channel region and the first and second cell source/drain regions are in a cell active pattern;
a gate dielectric layer in contact with the vertical channel region; and
the word line in contact with the gate dielectric layer, and
wherein the data storage structure includes a first electrode electrically connected to the second cell source/drain region, a dielectric layer on the first electrode, and a second electrode on the dielectric layer.

6. The semiconductor device of claim 5, wherein the vertical channel transistor is between the data storage structure and the second structure.

7. The semiconductor device of claim 5, wherein the data storage structure is between the vertical channel transistor and the second structure.

8. The semiconductor device of claim 5,
wherein the first structure further includes bit lines electrically connected to the memory cells and crossing the memory block region in a second direction intersecting the word line,
wherein the through-insulating pattern is a first through-insulating pattern, the peripheral transistor is a first peripheral transistor, the peripheral channel region is a first peripheral channel region, and the peripheral gate is a first peripheral gate,
wherein the second structure further includes:
a second through-insulating pattern in the semiconductor body; and
a second peripheral transistor including a third peripheral source/drain, fourth peripheral source/drain, second peripheral channel region between the third and fourth peripheral source/drains, and a second peripheral gate on the second peripheral channel region,
wherein the third and fourth peripheral source/drains and the second peripheral channel region are in a second peripheral active region among the peripheral active regions,
wherein the first and second structures further include a first bit line signal path electrically connecting a first bit line among the bit lines to the second peripheral transistor,
wherein the first bit line signal path further includes:
a first bit line routing peripheral structure electrically connected to the second peripheral transistor and on the semiconductor body;
a first bit line contact that is in contact with the first bit line;
a first bit line routing lower structure electrically connected to the first bit line contact; and
a first bit line routing connection structure electrically connecting the first bit line routing lower structure to the first bit line routing peripheral structure, and
wherein the first bit line routing connection structure includes a first bit line routing through-via vertically overlapping the memory block region and penetrating through the semiconductor body.

9. The semiconductor device of claim 8, wherein the first structure further includes a conductive shield structure including line portions between the bit lines and a connection portion extending from the line portions and on the bit lines.

10. The semiconductor device of claim 8,
wherein the extension region is a first extension region,
wherein the second structure further has a second extension region adjacent to the memory block region in a second direction perpendicular to the first direction,
wherein the first bit line crosses the memory block region and extends into the second extension region,
wherein the first bit line contact is in contact with the first bit line in the second extension region,
wherein the first bit line routing lower structure extends from the second extension region into the memory block region, and
wherein the first bit line routing lower structure is in contact with the first bit line contact in the second extension region and is in contact with the first bit line routing through-via in the memory block region.

11. The semiconductor device of claim 8,
wherein the first bit line contact is in contact with the first bit line in the memory block region, and
wherein the first bit line routing lower structure electrically connects the first bit line contact to the first bit line routing through-via in the memory block region.

12. The semiconductor device of claim 1,
wherein the second structure includes a first peripheral interconnection structure on the semiconductor body and a second peripheral interconnection structure on the first peripheral interconnection structure,
wherein the first peripheral interconnection structure includes:
vertical plugs;
first horizontal portions at a level higher than a level of the vertical plugs;
first vertical vias on the first horizontal portions;
second horizontal portions at a level higher than a level of the first vertical vias;
second vertical vias at a level higher than a level of the second horizontal portions; and
third horizontal portions at a level higher than a level of the second vertical vias.

13. The semiconductor device of claim 12,
wherein the word line routing peripheral structure includes:
a first peripheral routing contact plug, among the vertical plugs, electrically connected to the first peripheral source/drain;
a first peripheral routing lower interconnection line, among the first horizontal portions, electrically connected to the first peripheral routing contact plug;
a first peripheral routing via, among the first vertical vias, electrically connected to the first peripheral routing lower interconnection line; and
a first peripheral routing upper interconnection line, among the second horizontal portions, electrically connected to the first peripheral routing via, and
wherein an upper surface of the word line routing through-via is in contact with a lower surface of the first peripheral routing upper interconnection line.

14. The semiconductor device of claim 12,
wherein the word line routing peripheral structure includes:
a first peripheral routing contact plug, among the vertical plugs, electrically connected to the first peripheral source/drain; and
a peripheral routing lower interconnection line, among the first horizontal portions, in contact with an upper surface of the word line routing through-via.

15. The semiconductor device of claim 12,
wherein the second peripheral interconnection structure includes:
first vias at different vertical levels; and
peripheral interconnection lines electrically connected to the first vias and at different vertical levels,
wherein the first peripheral interconnection structure includes a first conductive material, and
wherein the second peripheral interconnection structure includes a second conductive material different from the first conductive material.

16. The semiconductor device of claim 1, wherein the word line routing connection structure further includes:
a first bonding pad electrically connected to the word line routing lower structure; and
a second bonding pad electrically connected to the word line routing through-via and in contact with the first bonding pad.

17. A semiconductor device comprising:
a first structure having a memory block region and an extension region adjacent to the memory block region in a first direction; and
a second structure vertically overlapping the first structure and having a peripheral circuit region vertically overlapping the memory block region,
wherein the first structure includes:
memory cells in the memory block region and each including a vertical channel transistor and a data storage structure;
a word line electrically connected to the memory cells, crossing the memory block region and extending into the extension region; and
a bit line electrically connected to the memory cells and crossing the memory block region,
wherein the second structure includes a semiconductor body, a first peripheral transistor, a second peripheral transistor, and through-insulating patterns in the semiconductor body,
wherein the first and second structures include a first word line signal path electrically connecting the word line to the first peripheral transistor and a bit line signal path electrically connecting the bit line to the second peripheral transistor,
wherein the first word line signal path includes:
a word line routing through-via penetrating through a first through-insulating pattern among the through-insulating patterns and vertically overlapping the memory block region;
a word line contact that is in contact with the word line in the extension region; and
a word line routing lower structure electrically connecting the word line contact to the word line routing through-via,
wherein the bit line signal path includes:
a bit line routing through-via penetrating through a second through-insulating pattern among the through-insulating patterns and vertically overlapping the memory block region;
a bit line contact that is in contact with the bit line; and
a bit line routing lower structure electrically connecting the bit line contact to the bit line routing through-via,
wherein lower surfaces of the word line routing through-via and the bit line routing through-via are at a level lower than a level of lower surfaces of the through-insulating patterns, and
wherein upper surfaces of the word line routing through-via and the bit line routing through-via are at a level higher than a level of upper surfaces of the through-insulating patterns.

18. The semiconductor device of claim 17,
wherein the second structure further includes:
a backside insulating layer below the semiconductor body and the through-insulating patterns; and
an isolation region defining peripheral active regions on the semiconductor body,
wherein a lower surface of the semiconductor body and lower surfaces of the through-insulating patterns are in contact with the backside insulating layer, and
wherein the word line routing through-via and the bit line routing through-via penetrate through at least a portion of the backside insulating layer.

19. A semiconductor device comprising:
a first structure having a first memory block region and a second memory block region adjacent to each other in a first direction, and an extension region between the first memory block region and the second memory block region; and
a second structure vertically overlapping the first structure, and including a first peripheral circuit region vertically overlapping the first memory block region, and a second peripheral circuit region vertically overlapping the second memory block region,
wherein the first structure includes:
memory cells in the first and second memory block regions, respectively, and each including a vertical channel transistor and a data storage structure; and
a word line crossing the first and second memory block regions and the extension region and electrically connected to the memory cells in the first and second memory block regions,
wherein the second structure includes a semiconductor body, peripheral transistors and through-insulating patterns in the semiconductor body,
wherein the first and second structures include a first word line signal path electrically connecting the word line to a first peripheral transistor among the peripheral transistors,
wherein the first word line signal path includes:
a word line routing through-via penetrating through a first through-insulating pattern among the through-insulating patterns and vertically overlapping the first memory block region;
a word line contact that is in contact with the word line in the extension region; and
a word line routing lower structure electrically connecting the word line contact to the word line routing through-via,
wherein a lower surface of the word line routing through-via is at a level lower than a level of lower surfaces of the through-insulating patterns, and
wherein an upper surface of the word line routing through-via is at a level higher than a level of upper surfaces of the through-insulating patterns.

20. The semiconductor device of claim 19,
wherein the extension region is a first extension region,
wherein the first structure further has a third memory block region adjacent to the first memory block region in a second direction perpendicular to the first direction, and a second extension region between the first and third memory block regions,
wherein the first structure includes:
a first bit line crossing the first memory block region in the second direction and electrically connected to the memory cells of the first memory block region; and
a second bit line crossing the third memory block region in the second direction and electrically connected to the memory cells of the third memory block region,
wherein the first and second structures further includes:
a first bit line signal path electrically connecting the first bit line to a second peripheral transistor among the peripheral transistors; and
a second bit line signal path electrically connecting the second bit line to a third peripheral transistor among the peripheral transistors,
wherein the second and third peripheral transistors vertically overlap the first memory block region,
wherein the first bit line signal path penetrates through a second through-insulating pattern among the through-insulating patterns and includes a first bit line routing through-via vertically overlapping the first memory block region, and
wherein the second bit line signal path penetrates through a third through-insulating pattern among the through-insulating patterns and includes a second bit line routing through-via not vertically overlapping the first memory block region.
